(19) United States
(12) Patent Application Publication
(10) Pub. No.: US 2025/0194330 A1
(43) Pub. Date: Jun. 12, 2025

(54) LIGHT-EMITTING ELEMENT, DISPLAY DEVICE INCLUDING THE SAME AND METHOD OF FABRICATING THE SAME

(71) Applicant: Samsung Display Co., LTD., Yongin-si (KR)

(72) Inventors: Su Mi MOON, Yongin-si (KR); Min Woo KIM, Yongin-si (KR); Hoo Keun PARK, Yongin-si (KR); Chae Woo CHUNG, Yongin-si (KR)

(21) Appl. No.: 18/965,897

(22) Filed: Dec. 2, 2024

(30) Foreign Application Priority Data
Dec. 7, 2023 (KR) 10-2023-0176362

(51) Int. Cl. H01L 21/02

(52) U.S. Cl. CPC H10H 29/8421; H10H 29/012; H10H 29/03; H10H 29/37

(57) ABSTRACT

A light emitting element includes a first element rod including a first semiconductor layer and an active layer and having a first inclination angle on a side surface; a second element rod on the first element rod and having a second inclination angle on a side surface; a third element rod on the second element rod and having a third inclination angle on a side surface, the second inclination angle being smaller than the first inclination angle and the third inclination angle; a protective layer around one side and an other side of the first element rod, a side of the second element rod, and a side of the third element rod; and a contact electrode around the protective layer and electrically connected to the first semiconductor layer.

### CROSS-REFERENCE TO RELATED APPLICATION

The present application claims priority to and the benefit of Korean Patent Application No. 10-2023-0176362, filed on Dec. 7, 2023, in the Korean Intellectual Property Office, the entire disclosure of which is incorporated by reference herein.

### BACKGROUND

### 1. Field

The present disclosure relates to a light emitting element, a display device including the same, and a method of fabricating the same.

### 2. Description of the Related Art

With the development of the information society, the demand for display devices for displaying images is increasing in various forms. The display device may be a flat panel display such as a liquid crystal display, a field emission display, a light emitting display, and the like.

The light emitting display device may be implemented as an organic light emitting display device including an organic light emitting diode (OLED) element as the light emitting element, an inorganic light emitting display device including an inorganic semiconductor element as the light emitting element, or a ultra-small light emitting diode display device including a ultra-small light emitting diode element (or micro light emitting diode element) as the light emitting element.

### SUMMARY

Aspects and features of embodiments of the present disclosure provide a method of manufacturing a display device that may secure the width of the active layer relative to the width of the light emitting element while reducing or minimizing damage to the active layer, and a light emitting element and a display device fabricated by using the method.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to one or more embodiments, a light emitting element includes a first element rod including a first semiconductor layer and an active layer and having a first inclination angle on a side surface; a second element rod on the first element rod and having a second inclination angle on a side surface; a third element rod on the second element rod and having a third inclination angle on a side surface, the second inclination angle being smaller than the first inclination angle and the third inclination angle; a protective layer around one surface and a side of the first element rod, a side of the second element rod, and a side of the third element rod; and a contact electrode around the protective layer and electrically connected to the first semiconductor layer.

According to one or more embodiments, the second inclination angle is in a range from 60 degrees to 80 degrees.

According to one or more embodiments, the protective layer includes a first insulating layer around the one surface and the side of the first element rod, and the side of the second element rod; a reflective layer around the one surface and the side of the first element rod and the side of the second element rod on the first insulating layer; and a second insulating layer around the one surface and the side of the first element rod, the side of the second element rod, and the side of the third element rod on the reflective layer.

According to one or more embodiments, the first insulating layer and the reflective layer are not on the side of the third element rod.

According to one or more embodiments, the second element rod is wider toward the third element rod, and a width of the third element rod is greater than a width of the first element rod.

According to one or more embodiments, the contact electrode extends from one surface of the first element rod and is on at least a portion of the side of the first element rod, the side of the second element rod, and the side of the third element rod.

According to one or more embodiments, a light emitting element includes an element rod including a first semiconductor layer, an active layer, a second semiconductor layer, and a third semiconductor layer stacked in order, and divided into a first element rod, a second element rod, and a third element rod according to an inclination angle, the first element rod including the first semiconductor layer and an active layer, the inclination angle including a first inclination angle, a second inclination angle, and a third inclination angle, the second inclination angle of the second element rod being smaller than the first inclination angle of the first element rod and the third inclination angle of the third element rod; a protective layer around one surface and a side of the first element rod, a side of the second element rod, and a side of the third element rod; and a first contact electrode and a second contact electrode spaced from each other on one surface of the first element rod, the first contact electrode electrically connected with the first semiconductor layer, the second contact electrode being electrically connected with the second semiconductor layer.

According to one or more embodiments, the protective layer includes a first insulating layer around the one surface and the side of the first element rod and the side of the second element rod; a reflective layer around the one surface and the side of the first element rod and the side of the second element rod on the first insulating layer; and a second insulating layer around the one surface and the side of the first element rod, the side of the second element rod, and the side of the third element rod on the reflective layer.

According to one or more embodiments, the first contact electrode and the second contact electrode are disposed on at least a portion of a side surface of the element rod on the protective layer.

According to one or more embodiments, a display device incudes a substrate; a pixel electrode on the substrate; a light emitting element on the pixel electrode and including a contact electrode on one surface; a connection electrode connecting the contact electrode and the pixel electrode; and a common electrode on the light emitting element, the light emitting element further includes a first element rod including a first semiconductor layer and an active layer and having a first inclination angle on a side surface; a second element rod on the first element rod and having a second inclination angle on a side surface; a third element rod on the second element rod and having a third inclination angle on a side surface; and a protective layer around one surface and a side of the first element rod, a side of the second element rod, and a side of the third element rod, the contact electrode being around at least a portion of a side of the protective layer, and the second inclination angle being smaller than the first inclination angle and the third inclination angle.

According to one or more embodiments, the second inclination angle is in a range from 60 degrees to 80 degrees.

According to one or more embodiments, the protective layer includes a first insulating layer around the one surface and the side of the first element rod and the side of the second element rod; a reflective layer around the one surface and the side of the first element rod and the side of the second element rod on the first insulating layer; and a second insulating layer around the one surface and the side of the first element rod, the side of the second element rod, and the side of the third element rod on the reflective layer.

According to one or more embodiments, the first insulating layer and the reflective layer are not on the side of the third element rod.

According to one or more embodiments, the contact electrode extends from the one surface of the first element rod and is on at least a portion of the side of the first element rod, the side of the second element rod, and the side of the third element rod.

According to one or more embodiments, the display device further includes an organic pattern layer between the light emitting element and the pixel electrode, wherein the connection electrode is on a portion of a side surface of the organic pattern layer and a side surface of the contact electrode on the pixel electrode.

According to one or more embodiments, a display device includes a substrate; a pixel electrode and a common electrode on the substrate and spaced from each other; a light emitting element on the pixel electrode and the common electrode and including a first contact electrode and a second contact electrode on one surface; a first connection electrode connected to the pixel electrode and the first contact electrode; and a second connection electrode connected to the common electrode and the second contact electrode, the light emitting element including an element rod including a first semiconductor layer, an active layer, a second semiconductor layer, and a third semiconductor layer stacked in order, and divided into a first element rod, a second element rod, and a third element rod according to an inclination angle, the inclination angle including a first inclination angle, a second inclination angle, and a third inclination angle, the second inclination angle of the second element rod being smaller than the first inclination angle of the first element rod and the third inclination angle of the third element rod; and a protective layer around one surface and a side of the first element rod, a side of the second element rod, and a side of the third element rod, and the first contact electrode and the second contact electrode being spaced from each other on one surface of the first element rod and on at least a portion of a side surface of the element rod on the protective layer.

According to one or more embodiments, the protective layer includes a first insulating layer around the one surface and the side of the first element rod and the side of the second element rod; a reflective layer around the one surface and the side of the first element rod and the side of the second element rod on the first insulating layer; and a second insulating layer around the one surface and the side of the first element rod, the side of the second element rod, and the side of the third element rod on the reflective layer.

According to one or more embodiments, the display device further includes an organic pattern layer between the pixel electrode and the common electrode, wherein the light emitting element is on the organic pattern layer, wherein the first connection electrode is on a portion of a side surface of the organic pattern layer and a side surface of the first contact electrode, and wherein the second connection electrode is on another part of the side surface of the organic pattern layer and a side surface of the second contact electrode.

According to one or more embodiments, a method of manufacturing light emitting element includes forming a third semiconductor material layer, a second semiconductor material layer, an active material layer, and a first semiconductor material layer on a growth substrate; forming a first element rod having a first inclination angle by etching the active material layer and the first semiconductor material layer using a first mask; masking the first element rod using a second mask and etching the second semiconductor material layer and the third semiconductor material layer; forming a first insulating layer and a first reflective layer covering the third semiconductor material layer, the second semiconductor material layer, the active material layer, and the first semiconductor material layer; forming a second element rod having a second inclination angle and a third element rod having a third inclination angle by etching at least one side surface of at least one of the first, second, and third semiconductor material layers, the first insulating layer, and the first reflective layer using a third mask; forming a second insulating layer covering the third semiconductor material layer, the second semiconductor material layer, the active material layer, and the first semiconductor material layer; and forming a contact electrode on the second insulating layer.

According to one or more embodiments, a method of manufacturing display device includes forming a third semiconductor material layer, a second semiconductor material layer, an active material layer, and a first semiconductor material layer on a growth substrate; forming a first element rod having a first inclination angle by etching the active material layer and the first semiconductor material layer using a first mask; masking the first element rod using a second mask and then etching the second semiconductor material layer and the third semiconductor material layer; forming a first insulating layer and a first reflective layer covering the third semiconductor material layer, the second semiconductor material layer, the active material layer, and the first semiconductor material layer; forming a second element rod having a second inclination angle and a third element rod having a third inclination angle by etching at least one side surface of at least one of the first, second, and third semiconductor material layers, the first insulating layer, and the first reflective layer using a third mask; forming a second insulating layer covering the third semiconductor material layer, the second semiconductor material layer, the active material layer, and the first semiconductor material layer; forming a light emitting element by forming a contact electrode on the second insulating layer; transferring the light emitting element to a circuit board having a pixel electrode; and forming a connection electrode connecting the contact electrode and the pixel electrode.

According to a display device and a manufacturing method thereof according to one or more embodiments, it is possible to secure a sufficient width of the active layer relative to the chip size while reducing or minimizing damage to the active layer during processing.

However, the effects of the present disclosure are not limited to the aforementioned effects, and various other effects are included in the present disclosure.

### BRIEF DESCRIPTION OF THE DRAWINGS

FIG. 1 is a perspective view illustrating a display device according to one or more embodiments.

FIG. 2 is a layout diagram illustrating a display device according to one or more embodiments.

FIG. 3 is a block diagram illustrating a display device according to one or more embodiments.

FIG. 4 is an equivalent circuit diagram illustrating a sub-pixel according to one or more embodiments.

FIG. 5 is an equivalent circuit diagram illustrating a sub-pixel according to one or more embodiments.

FIG. 6 is a layout diagram illustrating a plurality of pixels in a display area according to one or more embodiments.

FIG. 7 is a cross-sectional view illustrating one example of a cross-section of a display panel corresponding to the line 11-11′ of FIG. 6.

FIGS. 8A and 8B are cross-sectional views illustrating one example of an area A of FIG. 7 in detail.

FIG. 9 is a cross-sectional view illustrating another example of the area A of FIG. 7 in detail.

FIG. 10 is a cross-sectional view illustrating another example of the area A of FIG. 7 in detail.

FIG. 11 is a cross-sectional view illustrating another example of the area A of FIG. 7 in detail.

FIG. 12 is a layout diagram illustrating pixels of a display area according to one or more embodiments.

FIG. 13 is a cross-sectional view illustrating one example of a cross-section of a display panel corresponding to the line 12-12′ in FIG. 12.

FIG. 14 is a cross-sectional view illustrating an example of an area B of FIG. 13 in detail.

FIGS. 15 and 16 are cross-sectional views illustrating another example of the area B of FIG. 13 in detail.

FIG. 17 is a flowchart illustrating a method of manufacturing a display device according to one or more embodiments.

FIGS. 18-33 are cross-sectional views to illustrate a method of manufacturing a display device according to one or more embodiments.

FIG. 34 is an example diagram schematically showing a virtual reality device including a display device according to one or more embodiments.

FIG. 35 is an example diagram schematically showing a smart device including a display device according to one or more embodiments.

FIG. 36 is a diagram of an example schematically showing a vehicle including a display device according to one or more embodiments.

FIG. 37 is a diagram of an example schematically showing a transparent display device including a display device according to one or more embodiments.

### DETAILED DESCRIPTION

Embodiments of the present disclosure will now be described more fully hereinafter with reference to the accompanying drawings. Embodiments may, however, be provided in different forms and should not be construed as limiting. The same reference numbers indicate the same components throughout the present disclosure. In the accompanying figures, the thickness of layers and regions may be exaggerated for clarity.

Some of the parts which are not associated with the description may not be provided in order to describe embodiments of the present disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “spaced from,” “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the present disclosure and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which the present disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, specific embodiments will be described with reference to the attached drawings.

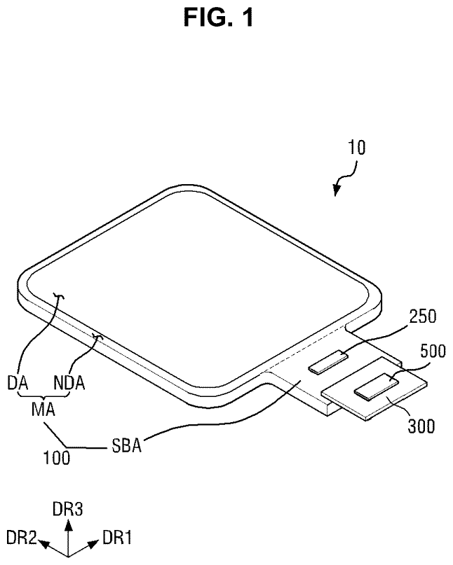

FIG. 1 is a perspective view illustrating a display device according to one or more embodiments.

Referring to FIG. 1, a display device 10 is a device for displaying video or still images, such as mobile phones, smart phones, tablet personal computers, and portable electronic devices such as smart watches, watch phones, mobile communication terminals, electronic notebooks, e-books, portable electronic devices such as portable multimedia players (PMP), navigation, and ultra mobile PCs (UMPC), as well as display screens for a variety of products such as televisions, laptops, monitors, billboards, and/or the internet of things (IoT).

The display device 10 may be a light emitting display device, such as an organic light-emitting display device utilizing an organic light-emitting diode (OLED), a quantum dot light-emitting display device including a quantum dot light-emitting layer, an inorganic light-emitting display device including an inorganic semiconductor, and a miniaturized light-emitting display device utilizing a micro or nano light emitting diode (micro LED or nano LED). Hereinafter, the description focuses on the fact that the display device 10 is a micro-light emitting display device, but the present disclosure is not limited thereto. On the other hand, a micro light emitting diode referred to as a light emitting diode in the following for convenience of explanation.

The display device 10 includes a display panel 100, a display driving circuit 250, a circuit board 300, and a power supply circuit 500.

The display panel 100 may be formed as a rectangular-shaped plane having a short side in the first direction DR1 and a long side in the second direction DR2 that intersects the first direction DR1. A corner where the short side in the first direction DR1 and the long side in the second direction DR2 meet may be rounded to have a suitable curvature (e.g., a predetermined curvature) or may be formed at a right angle. The planar shape of the display panel 100 is not limited to a rectangle, and may be formed in other polygonal, circular, or oval shapes. The display panel 100 may be formed flat but is not limited thereto. For example, the display panel 100 is formed at left and right ends and may include curved portions with a constant curvature or a changing curvature. Additionally, the display panel 100 may be formed to be flexible, such as to be able to be bent, curved, bent, folded, and/or rolled.

The substrate SUB of the display panel 100 may include a main area MA and a sub-area SBA.

The main area MA may include a display area DA that displays an image and a non-display area NDA that is a peripheral area of the display area DA and is around (e.g., surrounding) the display area DA along an edge or a periphery of the display area DA. The display area DA may include a plurality of pixels that display an image. For example, the pixel may include a first sub-pixel that emits first light, a second sub-pixel that emits second light, and a third sub-pixel that emits third light.

The sub-area SBA may protrude from one side of the main area MA in the second direction DR2. Although FIG. 1 illustrates the sub-area SBA being unfolded, the sub-area SBA may be bent, and in this case, may be disposed on the bottom surface of the display panel 100. When the sub-area SBA is bent, it may overlap the main area MA in the third direction DR3, which is the thickness direction of the display panel 100. The display driving circuit 250 may be disposed in the sub-area SBA.

The display driving circuit 250 may generate signals and voltages for driving the display panel 100. The display driving circuit 250 may be formed as an integrated circuit (IC) and attached to the display panel 100 using a chip-on-glass (COG) method, a chip-on-plastic (COP) method, or an ultrasonic bonding method but is not limited thereto. For example, the display driving circuit 250 may be attached to the circuit board 300 using a chip-on-film (COF) method.

The circuit board 300 may be attached to one end of the sub-area SBA of the display panel 100. As such, the circuit board 300 may be electrically connected to the display panel 100 and the display driving circuit 250. The display panel 100 and the display driving circuit 250 may receive digital video data, timing signals, and driving voltages through the circuit board 300. The circuit board 300 may be a flexible film, such as a flexible printed circuit board (FPCB), a printed circuit board (PCB), or a chip-on-film (COF).

The power supply circuit 500 (e.g., power supply unit) may generate and/or supply a plurality of panel-driving voltages according to an external power supply voltage. The power supply circuit 500 may be formed as an integrated circuit (IC) and attached to the circuit board 300 using a COF method.

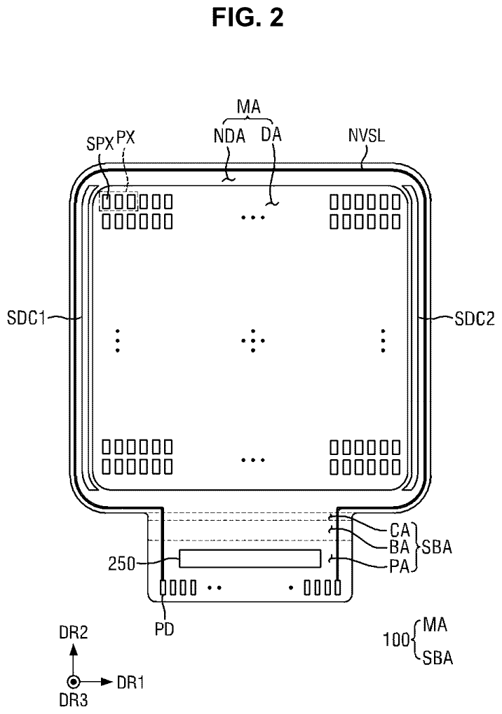

FIG. 2 is a layout diagram illustrating a display device according to one or more embodiments. FIG. 2 illustrates that the sub-area SBA is unfolded without being bent.

Referring to FIG. 2, the display panel 100 may include the main area MA and the sub-area SBA.

The main area MA may include the display area DA that displays an image and the non-display area NDA that is a peripheral area of the display area DA. The display area DA may occupy most of the main area MA. The display area DA may be placed in the center of the main area MA.

The display area DA may include a plurality of pixels PX for displaying an image, and each of the plurality of pixels PX may include a plurality of sub-pixels SPX. A pixel PX may be defined as a sub-pixel group of the smallest unit capable of expressing a white grayscale.

The non-display area NDA may be placed adjacent to the display area DA. The non-display area NDA may be an area outside the display area DA. The non-display area NDA may be arranged to be around (e.g., to surround) the display area DA. The non-display area NDA may be an edge area of the display panel 100.

A first scan driving unit (or a first scan driving portion) SDC1 and a second scan driving unit (or a second scan driving portion) SDC2 may be disposed in the non-display area NDA. The first scan driving unit SDC1 is disposed on one side (for example, the left side) of the display panel 100, and the second scan driving unit SDC2 is disposed on the other side (for example, the right side) of the display panel 100. However, it is not limited thereto. Each of the first scan driving unit SDC1 and the second scan driving unit SDC2 may be electrically connected to the display driving circuit 250 through scan fan-out lines. Each of the first scan driving unit SDC1 and the second scan driving unit SDC2 may receive a scan control signal from the display driving circuit 250, generate scan signals according to the scan control signal, and output them to the scan lines.

The sub-area SBA may protrude from one side of the main area MA in the second direction DR2. The length of the sub-area SBA in the second direction DR2 may be smaller than the length of the main area MA in the second direction DR2. The length in the first direction DR1 of the sub-area SBA is smaller than the length in the first direction DR1 of the main area MA or may be substantially equal to the length in the first direction DR1 of the main area MA. The sub-area SBA may be curved and may be disposed at the lower portion of the display panel 100. In this case, the sub-area SBA may overlap the main area MA in the third direction DR3.

The sub-area SBA may include a connection area CA, a pad area PA, and a bending area BA.

The connection area CA is an area protruding from one side of the main area MA in the second direction DR2. One side of the connection area CA may be in contact with the non-display area NDA of the main area MA, and the other side of the connection area CA may be in contact with the bending area BA.

The pad area PA is an area where the pads PD and the display driving circuit 250 are disposed. The display driving circuit 250 may be attached to the driving pads of the pad area PA using a conductive adhesive member such as an anisotropic conductive film. The circuit board 300 may be attached to the pads PD of the pad area PA using a conductive adhesive member such as an anisotropic conductive film. One side of the pad area PA may be in contact with the bending area BA.

The bending area BA is a bent area. When the bending area BA is bent, the pad area PA may be disposed below the connection area CA and below the main area MA (e.g., in a thickness direction (e.g., the third direction DR3)). The bending area BA may be disposed between the connection area CA and the pad area PA. One side of the bending area BA may be in contact with the connection area CA, and the other side of the bending area BA may be in contact with the pad area PA.

A non-display power supply line NVSL may be disposed in the non-display area NDA, the connection area CA, the bending area BA, and the pad area PA.

The non-display power supply line NVSL may be disposed on four sides of the display area DA in the non-display area NDA. The non-display power supply line NVSL may be arranged to be around (e.g., to surround) at least three sides of the display area DA. For example, the non-display power supply line NVSL may be around (e.g., may surround) the left, top, and right sides of the display area DA and may be disposed on at least a portion of the lower side. Further, the non-display power supply line NVSL may be disposed outside the first scan driving unit SDC1 and outside the second scan driving unit SDC2. For example, the non-display power supply line NVSL may be disposed on the left side of the first scan driving unit SDC1 and on the right side of the second scan driving unit SDC2. The non-display power supply line NVSL may be disposed at the edge of the first scan driving unit SDC1 and the substrate SUB and at the edge of the second scan driving unit SDC2 and the substrate SUB. Alternatively, the non-display power supply line NVSL may overlap the first scan driving unit SDC1 and the second scan driving unit SDC2.

The non-display power supply line NVSL may be disposed at the left and right edges of the connection area CA and the bending area BA. The non-display power supply line NVSL may be connected to a pad PD adjacent to one side edge and a pad PD adjacent to the other side edge from among the pads PD in the pad area PA. The non-display power supply line NVSL may be supplied with a second driving voltage VSS from a power supply circuit 500 disposed on the circuit board 300.

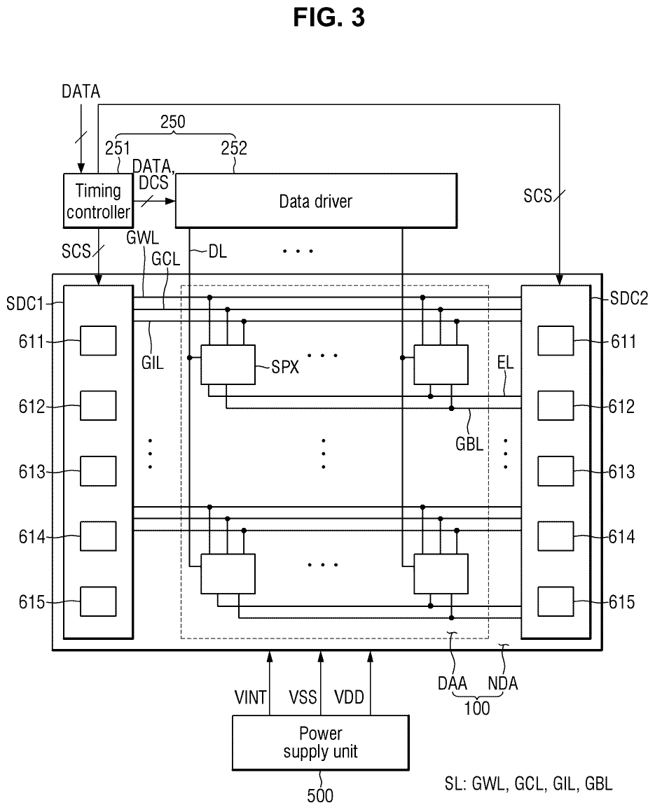

FIG. 3 is a block diagram illustrating a display device according to one or more embodiments.

Referring to FIG. 3, the display area DA includes a plurality of pixels PX, a plurality of scan lines SL, a plurality of emission control lines EL, and a plurality of data lines DL. According to one or more embodiments, each of the plurality of pixels PX includes a plurality of sub-pixels SPX

The plurality of pixels PX may be arranged in a matrix form in the first direction DR1 and the second direction DR2. For example, the plurality of pixels PX may be arranged along rows and columns of a matrix along the first direction DR1 and the second direction DR2. The plurality of scan lines SL and the plurality of emission control lines EL may extend in the first direction DR1 and may be arranged along the second direction DR2. The plurality of data lines DL may extend in the second direction DR2 and may be arranged along the first direction DR1. The plurality of scan lines SL may include a plurality of write scan lines GWL, a plurality of control scan lines GCL, a plurality of initialization scan lines GIL, and a plurality of bias scan lines GBL.

Each of the plurality of sub-pixels SPX may be connected to a write scan line GWL from among the plurality of write scan lines GWL, a control scan line GCL from among the plurality of control scan lines GCL, an initialization scan line GIL from among the plurality of initialization scan lines GIL, a bias scan line GBL from among the plurality of bias scan lines GBL, an emission control line EL from among the plurality of emission control lines EL, and a data line DL from among the plurality of data lines DL. Each of the plurality of sub-pixels SPX may be supplied with a data voltage of the data line DL according to the write scan signal of the write scan line GWL and may allow the light emitting elements to emit light according to the data voltage.

The non-display area NDA includes a first scan driving unit SDC1, a second scan driving unit SDC2, and a display driving circuit 250.

Each of the first scan driving unit SDC1 and the second scan driving unit SDC2 may include a write scan signal output unit 611, a control scan signal output unit 612, an initialization scan signal output unit 613, a bias scan signal output unit 614, and an light emitting signal output unit 615. Each of the write scan signal output unit 611, the control scan signal output unit 612, the initialization scan signal output unit 613, the bias scan signal output unit 614, and the light emitting signal output unit 615 may receive a scan timing control signal SCS from the timing control circuit (or timing controller) 251. The write scan signal output unit 611 may generate write scan signals according to the scan timing control signal SCS of the timing control circuit 251 and sequentially output them to the write scan lines GWL. The control scan signal output unit 612 may generate control scan signals according to the scan timing control signal SCS and sequentially output them to the control scan lines GCL. The initialization scan signal output unit 613 may generate initialization scan signals according to the scan timing control signal SCS and sequentially output them to the initialization scan lines GIL. The bias scan signal output unit 614 may generate bias scan signals according to the scan timing control signal SCS and sequentially output them to the bias scan lines GBL. The light emitting signal output unit 615 may generate light emitting control signals according to the scan timing control signal SCS and sequentially output them to the emission control lines EL.

The display driving circuit 250 includes a timing control circuit 251 and a data driving circuit (or data driver) 252.

The data driving circuit 252 may receive digital video data DATA and a data timing control signal DCS from the timing control circuit 251. The data driving circuit 252 converts digital video data DATA into analog data voltages according to the data timing control signal DCS and outputs them to the data lines DL. In this case, the sub-pixels SPX are selected by the write scan signals of the first scan driving unit SDC1 and the second scan driving unit SDC2, and data voltages may be supplied to the selected sub-pixels SPX.

The timing control circuit 251 may receive digital video data and timing signals from an external source. The timing control circuit 251 may generate the scan timing control signal SCS and the data timing control signal DCS to control the display panel 100 according to timing signals. The timing control circuit 251 may output the scan timing control signal SCS to the first scan driving unit SDC1 and the second scan driving unit SDC2. The timing control circuit 251 may output digital video data DATA and a data timing control signal DCS to the data driving circuit 252.

The data driving circuit 252 may receive digital video data DATA and a data timing control signal DCS from the timing control circuit 251.

The data driving circuit 252 may supply respective data signals (e.g., analog data voltages) to the sub-pixels SPX. For example, the data driving circuit 252 may convert the video data DATA into analog data voltages according to the data timing control signal DCS and output them to the data lines DL. Sub-pixels SPX may be selected by the write scan signals of the first scan driving unit SDC1 and the second scan driving unit SDC2, and data signals may be supplied to the selected sub-pixels SPX.

The power supply circuit 500 may generate a plurality of panel driving voltages according to an external power supply voltage. For example, the power supply circuit 500 may generate and may supply a first driving voltage VDD, a second driving voltage VSS, and a third driving voltage VINT to the display panel 100.

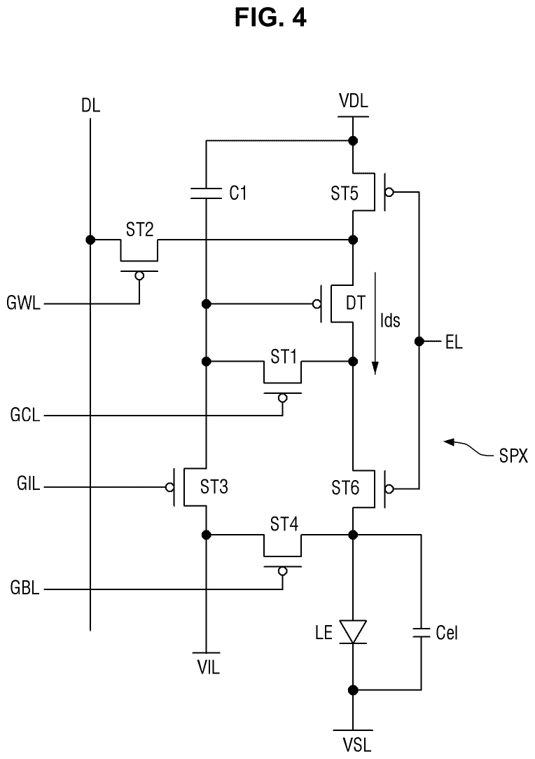

FIG. 4 is an equivalent circuit diagram illustrating a sub-pixel according to one or more embodiments.

Referring to FIG. 4, the sub-pixel SPX according to one or more embodiments may be connected to scan lines GWL, GIL, GCL, and GBL, an emission control line EL, and a data line DL. For example, the sub-pixel SPX may be connected to the write scan line GWL, the initialization scan line GIL, the control scan line GCL, the bias scan line GBL, the emission control line EL, and the data line DL.

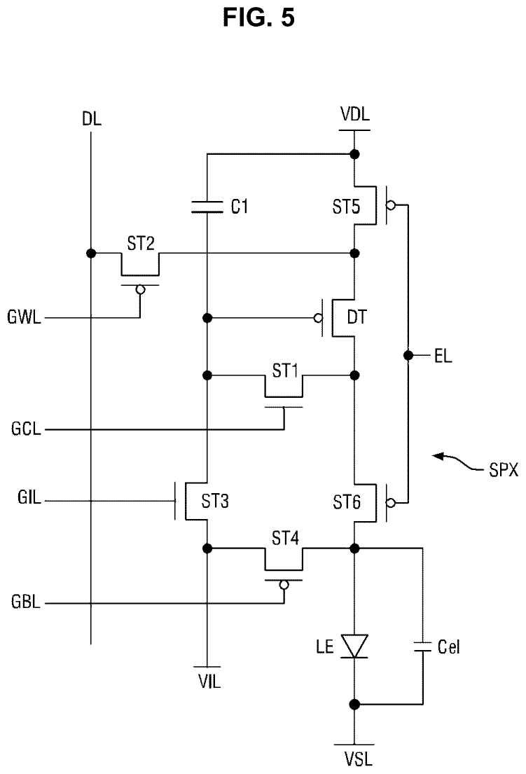

The sub-pixel SPX according to one or more embodiments includes a driving transistor DT, switch elements, a capacitor C1, and a light emitting element LE. The switch elements include first to sixth transistors ST1, ST2, ST3, ST4, ST5, and ST6. The driving transistor DT, switch elements, and capacitor C1 may be referred to as a pixel circuit. The pixel circuit may include a driving transistor DT, at least one switching transistor ST (e.g., ST1, ST2, ST3, ST4, ST5, and ST6), and a capacitor C1. In one or more embodiments, the pixel circuit may include first to sixth transistors ST1, ST2, ST3, ST4, ST5, and ST6 as the switching transistor ST. The configuration of the pixel circuit is not limited to the embodiments of FIGS. 4 and 5 and may be changed in various ways.

The driving transistor DT includes a gate electrode, a first electrode, and a second electrode. The driving transistor DT controls the drain-source current (e.g., Ids, hereinafter referred to as “driving current”) flowing between the first electrode and the second electrode according to the data voltage applied to the gate electrode.

The light emitting element LE may be a micro light emitting diode.

The light emitting element LE emits light according to the driving current Ids. The amount of light emitted from the light emitting element LE may be proportional to the driving current Ids. The anode electrode of the light emitting element LE is connected to the second electrode of the fourth transistor ST4 and the second electrode of the sixth transistor ST6, and the cathode electrode may be connected to a second power supply line VSL to which a second power supply voltage is applied. A parasitic capacitance Cel may be formed between the anode electrode and the cathode electrode of the light emitting element LE.

The capacitor C1 is formed between the gate electrode of the driving transistor DT and the first power supply line VDL to which the first power supply voltage is applied. The first power supply voltage may be at a higher level than the second power supply voltage. One electrode of the capacitor C1 may be connected to the gate electrode of the driving transistor DT, and the other electrode may be connected to the first power supply line VDL.

As shown in FIG. 4, the first to sixth transistors ST1, ST2, ST3, ST4, ST5, and ST6 and the driving transistor DT may all be formed as P-type metal oxide semiconductor field effect transistors (P-type MOSFETs). In this case, the active layer of each of the first to sixth transistors ST1, ST2, ST3, ST4, ST5, and ST6 and the driving transistor DT may be formed of polysilicon.

The gate electrode of the second transistor ST2 may be connected to the write scan line GWL, and the gate electrode of the first transistor ST1 may be connected to the control scan line GCL. The gate electrode of the third transistor ST3 may be connected to the initialization scan line GIL, and the gate electrode of the fourth transistor ST4 may be connected to the bias scan line GBL. The gate electrodes of the fifth and sixth transistor ST5 and ST6 may be connected to the emission control line EL. Because the first to sixth transistors ST1, ST2, ST3, ST4, ST5, and ST6 are formed as P-type MOSFET, they may be turned on when a scan signal of the gate low voltage and an emission signal (e.g., of a low voltage) are applied to the control scan line GCL, the initialization scan line GIL, the write scan line GWL, the bias scan line GBL, and the emission control line EL, respectively. One electrode of the third transistor ST3 and one electrode of the fourth transistor ST4 may be connected to an initialization voltage line VIL.

For example, the first transistor ST1 may be connected between the second electrode and the gate electrode of the driving transistor DT. The second transistor ST2 may be connected between the data line DL and the first electrode of the driving transistor DT. The third transistor ST3 may be connected between the initialization voltage line VIL and the gate electrode of the driving transistor DT. The fourth transistor ST4 may be connected between the initialization voltage line VIL and the light-emitting element LE. The fifth transistor ST5 may be connected between the first power supply line VDL and the first electrode of the driving transistor DT. The sixth transistor ST6 may be connected between the second electrode of the driving transistor DT and the light-emitting element LE.

FIG. 5 is an equivalent circuit diagram illustrating a sub-pixel according to one or more embodiments.

Referring to FIG. 5, the driving transistor DT, the second transistor ST2, the fourth transistor ST4, the fifth transistor ST5, and the sixth transistor ST6 are formed of P-type MOSFET, and the first transistor ST1 and the third transistor ST3 may be formed as N-type MOSFET. The active layer of each of the driving transistor DT, the second transistor ST2, the fourth transistor ST4, the fifth transistor ST5, and the sixth transistor ST6 formed as the P-type MOSFET may be formed of polysilicon, and the active layer of each of the first transistor ST1 and the third transistor ST3 formed as the N-type MOSFET may be formed of the oxide semiconductor. In this case, transistors formed of polysilicon and transistors formed of oxide semiconductors may be arranged in different layers.

Because the first transistor ST1 and the third transistor ST3 are formed as N-type MOSFET, the first transistor ST1 may be turned on when a control scan signal with a gate high voltage is applied to the control scan line GCL, and the third transistor ST3 may be turned on when an initialization scan signal is applied to the initialization scan line GIL. In comparison, the second transistor ST2, the fourth transistor ST4, the fifth transistor ST5, and the sixth transistor ST6 are formed as P-type MOSFET, so they may be turned on when a scan signal with a gate low voltage and an emission signal (e.g., with a low voltage) are applied to the write scan line GWL, the bias scan line GBL, and the emission control line EL, respectively.

Alternatively, the fourth transistor ST4 in FIG. 4 may be formed of the N-type MOSFET. In this case, the active layer of each fourth transistor ST4 may be formed of the oxide semiconductor. When the fourth transistor ST4 is formed of N-type MOSFET, it may be turned on when a bias scan signal of a gate high voltage is applied to the bias scan line GBL.

In one or more embodiments, the first to sixth transistors ST1, ST2, ST3, ST4, ST5, and ST6 and the driving transistor DT may all be formed as N-type MOSFET. In this case, the active layer of each of the first to sixth transistors ST1, ST2, ST3, ST4, ST5, and ST6 and the driving transistor DT may be formed of an oxide semiconductor.

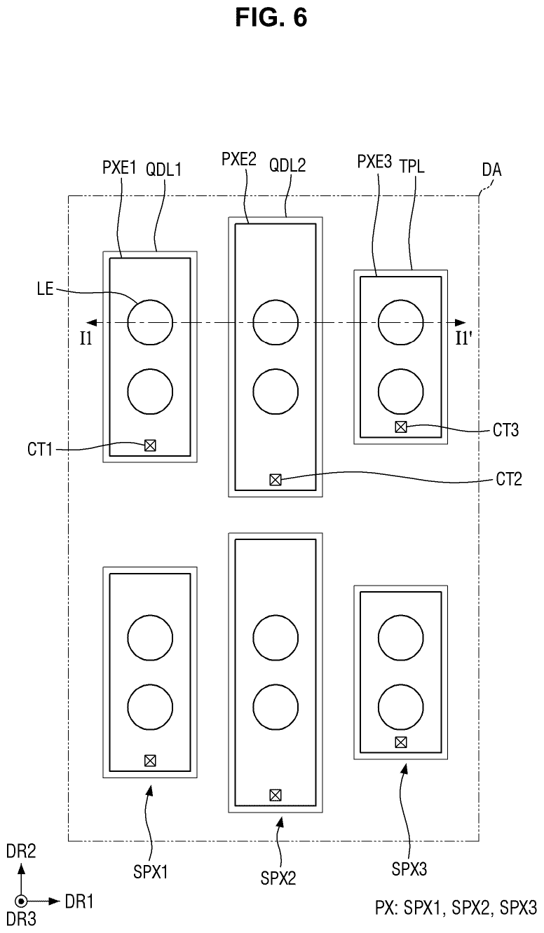

FIG. 6 is a layout diagram illustrating a plurality of pixels in a display area according to one or more embodiments.

Referring to FIG. 6, each of the plurality of pixels PX in the display area DA may include a first sub-pixel SPX1, a second sub-pixel SPX2, and a third sub-pixel SPX3.

A plurality of pixels PX may be arranged in a matrix form. In each of the plurality of pixels PX, the first sub-pixel SPX1, the second sub-pixel SPX2, and the third sub-pixel SPX3 may be arranged along the first direction DR1.

The first sub-pixel SPX1 may emit a first light, the second sub-pixel SPX2 may emit a second light, and the third sub-pixel SPX3 may emit a third light. Here, the first light may be light in a red wavelength band, the second light may be light in a green wavelength band, and the third light may be light in a blue wavelength band. For example, the blue wavelength band may refer to a main peak wavelength of the light being included in a wavelength band from about 370 μm to 460 μm, the green wavelength band may refer to a main peak wavelength of the light being included in a wavelength band from about 480 μm to 560 μm, and the red wavelength band may refer to a main peak wavelength of the light being included in a wavelength band from about 600 μm to 750 μm. However, the present disclosure is not limited thereto, and each of the first sub-pixel SPX1, the second sub-pixel SPX2, and the third sub-pixel SPX3 may output any one of the first light, the second light, and the third light.

The first sub-pixel SPX1 includes a first pixel electrode PXE1, a plurality of light emitting elements LE, and a first light conversion layer QDL1. The second sub-pixel SPX2 includes a second pixel electrode PXE2, a plurality of light emitting elements LE, and a second light conversion layer QDL2. The third sub-pixel SPX3 includes a third pixel electrode PXE3, a plurality of light emitting elements LE, and a light transmission layer TPL.

When the light emitting elements LE of the first sub-pixel SPX1, the light emitting elements LE of the second sub-pixel SPX2, and the light emitting elements LE of the third sub-pixel SPX3 emit light in the blue wavelength band, a first light conversion layer QDL1 and a second light conversion layer QDL2 are required for wavelength conversion. However, the present disclosure is not limited to this. When the light emitting elements LE of the first sub-pixel SPX1 emit light of the first color, the light emitting elements LE of the second sub-pixel SPX2 emit light of the second color, and the light emitting elements LE of the third sub-pixel SPX3 emit light of the third color, the first light conversion layer QDL1, the second light conversion layer QDL2, and the light transmission layer TPL may be omitted. Each of the first pixel electrode PXE1, the second pixel electrode PXE2, and the third pixel electrode PXE3 may have a rectangular planar shape with a short side in the first direction DR1 and a long side in the second direction DR2. Depending on the light conversion efficiency of the first light conversion layer QDL1 and the light conversion efficiency of the second light conversion layer QDL2, an area of the first sub-pixel SPX1, an area of the second sub-pixel SPX2, and an area of the third sub-pixel SPX3 may be set.

For example, as shown in FIG. 6, the area of the second pixel electrode PXE2 may be larger than the area of the first pixel electrode PXE1, and the area of the first pixel electrode PXE1 may be larger than the area of the third pixel electrode PXE3. When the length of the first pixel electrode PXE1 in the first direction DR1, the length of the second pixel electrode PXE2 in the first direction DR1, and the length of the third pixel electrode PXE3 in the first direction DR1 are the same, the length of the second pixel electrode PXE2 in the second direction DR2 is greater than the length of the first pixel electrode PXE1 in the second direction DR2, and the length of the first pixel electrode PXE1 in the second direction DR2 is greater than the length of the third pixel electrode PXE3 in the second direction DR2. However, the present disclosure is not limited to this, and the length of the first pixel electrode PXE1 in the first direction DR1, the length of the second pixel electrode PXE2 in the first direction DR1, and the length of the third pixel electrode PXE3 in the first direction DR1 may be the same, the length of the first pixel electrode PXE1 in the second direction DR2, the length of the second pixel electrode PXE2 in the second direction DR2, and the length of the third pixel electrode PXE3 in the second direction DR2 may be different. Alternatively, the length of the first pixel electrode PXE1 in the second direction DR2, the length of the second pixel electrode PXE2 in the second direction DR2, and the length of the third pixel electrode PXE3 in the second direction DR2 may be the same, the length of the first pixel electrode PXE1 in the first direction DR1, the length of the second pixel electrode PXE2 in the first direction DR1, and the length of the third pixel electrode PXE3 in the first direction DR1 may be different. Alternatively, the length of the first pixel electrode PXE1 in the first direction DR1, the length of the second pixel electrode PXE2 in the first direction DR1, the length of the third pixel electrode PXE3 in the first direction DR1, the length of the first pixel electrode PXE1 in the second direction DR2, the length of the second pixel electrode PXE2 in the second direction DR2, and the length of the third pixel electrode PXE3 in the second direction DR2 may be the same. Alternatively, the length in the first direction DR1 and the second direction DR2 of any two of the first pixel electrode PXE1, the second pixel electrode PXE2, and the third pixel electrode PXE3 may be the same as each other, and the length in the first direction DR1 and the second direction DR2 of the remaining one of the pixel electrodes may be different from the length in the first direction DR1 and the second direction DR2 of any two of the pixel electrodes.

The first pixel electrode PXE1 may be electrically connected to the second electrode of the fourth transistor (ST4 in FIGS. 4 and 5) and the second electrode of the sixth transistor (ST6 in FIGS. 4 and 5) of the first sub-pixel SPX1 through a first connection hole CT1. The second pixel electrode PXE2 may be electrically connected to the second electrode of the fourth transistor (ST4 in FIGS. 4 and 5) and the second electrode of the sixth transistor (ST6 in FIGS. 4 and 5) of the second sub-pixel SPX2 through a second connection hole CT2. The third pixel electrode PXE3 may be electrically connected to the second electrode of the fourth transistor (ST4 in FIGS. 4 and 5) and the second electrode of the sixth transistor (ST6 in FIGS. 4 and 5) of the third sub-pixel SPX3 through a third connection hole CT3.

A plurality of light emitting elements LE may be disposed on each of the first pixel electrode PXE1, the second pixel electrode PXE2, and the third pixel electrode PXE3. The same number of lights emitting elements LE may be disposed on each of the first pixel electrode PXE1, the second pixel electrode PXE2, and the third pixel electrode PXE3. For example, two light emitting elements LE may be disposed on each of the first pixel electrode PXE1, the second pixel electrode PXE2, and the third pixel electrode PXE3. The plurality of light emitting elements LE may emit third light, that is, light in the blue wavelength band.

However, the present disclosure is not limited to this, and one light emitting element LE may be disposed on each of the first pixel electrode PXE1, the second pixel electrode PXE2, and the third pixel electrode PXE3, or two or more light emitting elements LE, such as three light emitting elements LE or four light emitting elements LE, may be disposed. When two or more light emitting elements LE are disposed on each of the first pixel electrode PXE1, the second pixel electrode PXE2, and the third pixel electrode PXE3, even if a contact defect occurs between the light emitting element LE and the pixel electrode, the remaining light emitting element LE(s) may emit light by being in contact with the pixel electrode, so there is an advantage that repair is not required.

The first light conversion layer QDL1 may completely overlap the first pixel electrode PXE1 and the plurality of light emitting elements LE of the first sub-pixel SPX1. The area of the first light conversion layer QDL1 may be larger than the area of the first pixel electrode PXE1. The first light conversion layer QDL1 may convert or shift the peak wavelength of the incident light into light of another specific peak wavelength and emit it. For example, the first light conversion layer QDL1 may convert or shift the third light emitted from the plurality of light emitting elements LE of the first sub-pixel SPX1 into first light.

The second light conversion layer QDL2 may completely overlap the plurality of light emitting elements LE and the second pixel electrode PXE2 of the second sub-pixel SPX2. The area of the second light conversion layer QDL2 may be larger than the area of the second pixel electrode PXE2. The second light conversion layer QDL2 may convert or shift the peak wavelength of the incident light into light of another specific peak wavelength and emit it. For example, the second light conversion layer QDL2 may convert or shift the third light emitted from the plurality of light emitting elements LE of the second sub-pixel SPX2 into second light.

The light transmission layer TPL may completely overlap the plurality of light emitting elements LE and the third pixel electrode PXE3 of the third sub-pixel SPX3. The light transmission layer TPL may transmit incident light as it is. For example, the light transmission layer TPL may directly transmit the third light emitted from the plurality of light emitting elements LE of the third sub-pixel SPX3.

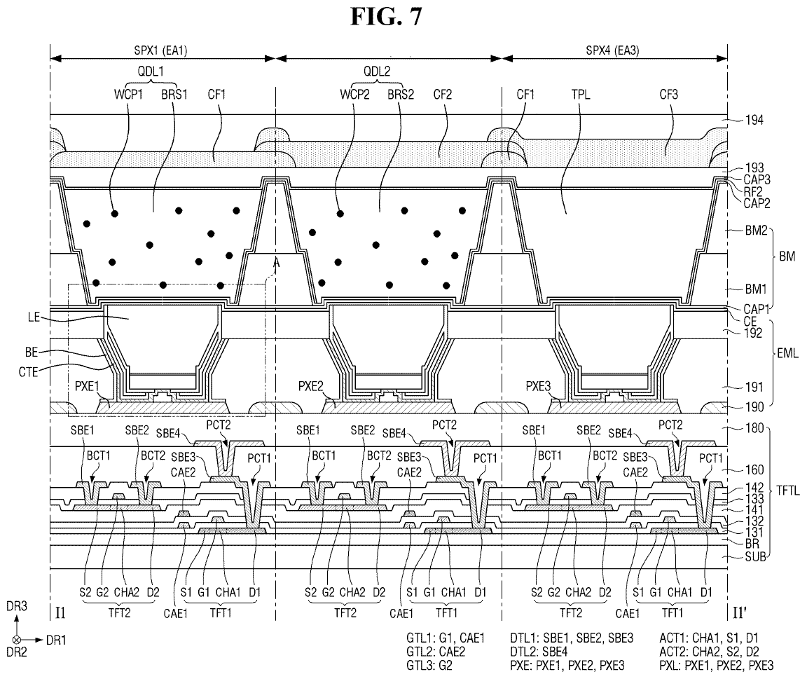

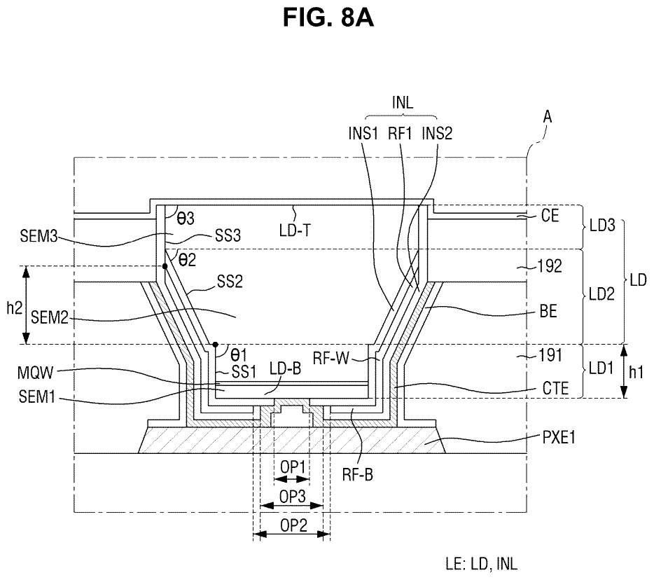

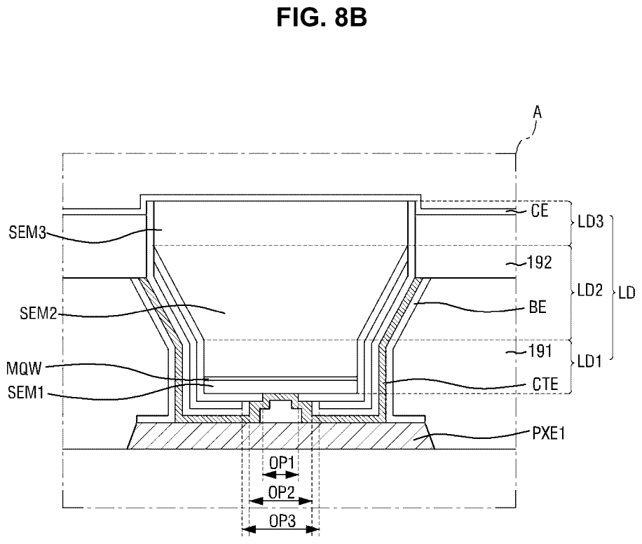

FIG. 7 is a cross-sectional view of a display panel corresponding to the line 11-11′ of FIG. 6. FIGS. 8A and 8B are cross-sectional views illustrating one example of an area A of FIG. 7 in detail.

Referring to FIGS. 7, 8A and 8B, a substrate SUB may be made of an insulating material such as glass, polymer resin, and/or the like. If the substrate SUB is made of polymer resin, it may be a flexible substrate that may be stretched. The polymer resin may be acrylic resin, epoxy resin, phenolic resin, polyamide resin, polyimide resin, and/or the like.

A barrier film BR may be disposed on the substrate SUB. The barrier film BR is a membrane for protecting the transistors of a thin film transistor layer TFTL and the light emitting element LE of a light emitting element layer EML from moisture penetrating through the substrate SUB, which is vulnerable to moisture penetration. The barrier film BR may be composed of a plurality of inorganic films stacked alternately. For example, the barrier film BR may be formed as a multilayer of alternating inorganic films of one or more of a silicon nitride layer, a silicon oxynitride layer, a silicon oxide layer, a titanium oxide layer, and/or an aluminium oxide layer.

A first thin film transistor TFT1 may be disposed on the barrier film BR. The first thin film transistor TFT1 may be either the fourth transistor ST4 or the sixth transistor ST6 shown in FIG. 5. The first thin film transistor TFT1 may include a first active layer ACT1 and a first gate electrode G1.

The first active layer ACT1 of the first thin film transistor TFT1 may be disposed on the barrier film BR. The first active layer ACT1 of the first thin film transistor TFT1 may include polycrystalline silicon, single crystalline silicon, low-temperature polycrystalline silicon, and/or amorphous silicon.

The first active layer ACT1 may include a first channel area CHA1, a first source area S1, and a first drain area D1. The first channel area CHA1 may be an area overlapping the first gate electrode G1 in the third direction DR3, which is the thickness direction of the substrate SUB. The first source area S1 may be disposed on one side of the first channel area CHA1, and the first drain area D1 may be disposed on the other side of the first channel area CHA1. The first source area S1 and the first drain area D1 may be areas that do not overlap with the first gate electrode G1 in the third direction DR3. The first source area S1 and the first drain area D1 may be areas in which the silicon semiconductor is doped with ions to make it conductive.

A first gate insulating film 131 may be disposed on the first channel area CHA1, the first source area S1, and the first drain area D1 of the first thin film transistor TFT1 and the barrier film BR. The first gate insulating film 131 may be formed of an inorganic film, for example, a silicon nitride film, a silicon oxynitride film, a silicon oxide film, a titanium oxide film, and/or an aluminium oxide film.

A first gate metal layer GTL1 may be disposed on the first gate insulating film 131. The first gate metal layer GTL1 may include the first gate electrode G1 and a first capacitor electrode CAE1 of the first thin film transistor TFT1. The first gate electrode G1 may overlap the first active layer ACT1 in the third direction DR3. In FIG. 7, the first gate electrode G1 and the first capacitor electrode CAE1 are shown to be spaced (e.g., disposed apart) from each other, but the first gate electrode G1 and the first capacitor electrode CAE1 may be connected to each other. The first gate metal layer GTL1 may be formed as a single layer or multiple layers of molybdenum (Mo), aluminium (Al), chromium (Cr), gold (Au), titanium (Ti), nickel (Ni), neodymium (Nd), and/or copper (Cu), and/or an alloy thereof.

A second gate insulating film 132 may be disposed on the first gate electrode G1 of the first thin film transistor TFT1, the first capacitor electrode CAE1, and the first gate insulating film 131. The second gate insulating film 132 may be formed of an inorganic film, for example, a silicon nitride film, a silicon oxynitride film, a silicon oxide film, a titanium oxide film, and/or an aluminium oxide film.

A second gate metal layer GTL2 may be disposed on the second gate insulating film 132. The second gate metal layer GTL2 may include a second capacitor electrode CAE2. The second capacitor electrode CAE2 may overlap the first capacitor electrode CAE1 in the third direction DR3. Because the second gate insulating film 132 has a suitable permittivity (e.g., a predetermined permittivity), a capacitor (C1 in FIG. 5) may be formed by the first capacitor electrode CAE1, the second capacitor electrode CAE2, and the second gate insulating film 132 disposed between them. The second gate metal layer GTL2 may be formed as a single layer or multiple layers of molybdenum (Mo), aluminium (Al), chromium (Cr), gold (Au), titanium (Ti), nickel (Ni), neodymium (Nd), and/or copper (Cu), and/or an alloy thereof.

A first interlayer insulating film 141 may be disposed on the second capacitor electrode CAE2 and the second gate insulating film 132. The first interlayer insulating film 141 may be formed of an inorganic film, such as a silicon nitride film, a silicon oxynitride film, a silicon oxide film, a titanium oxide film, and/or an aluminium oxide film.

A second thin film transistor TFT2 may be disposed on the first interlayer insulating film 141. The second thin film transistor TFT2 may be either the first transistor ST1 or the third transistor ST3 shown in FIG. 5. The second thin film transistor TFT2 may include a second active layer ACT2 and a second gate electrode G2.

The second active layer ACT2 of the second thin film transistor TFT2 may be disposed on the first interlayer insulating film 141. The second active layer ACT2 may include an oxide semiconductor. For example, the second active layer ACT2 may include IGZO (indium (In), gallium (Ga), zinc (Zn) and oxygen (O)), IGZTO (indium (In), gallium (Ga), zinc (Zn), tin (Sn) and/or oxygen (O)), and/or IGTO (indium (In), gallium (Ga), tin (Sn) and oxygen (O)).

The second active layer ACT2 may include a second channel area CHA2, a second source area S2, and a second drain area D2. The second channel area CHA2 may be an area that overlaps the second gate electrode G2 in the third direction DR3. The second source area S2 may be disposed on one side of the second channel area CHA2, and the second drain area D2 may be disposed on the other side of the second channel area CHA2. The second source area S2 and the second drain area D2 may be areas that do not overlap the second gate electrode G2 in the third direction DR3. The second source area S2 and the second drain area D2 may be areas in which the oxide semiconductor is doped with ions to make it conductive.

A third gate insulating film 133 may be disposed on the second active layer ACT2 of the second thin film transistor TFT2 and the first interlayer insulating film 141. The third gate insulating film 133 may be formed of an inorganic film, for example, a silicon nitride film, a silicon oxynitride film, a silicon oxide film, a titanium oxide film, and/or an aluminium oxide film.

A third gate metal layer GTL3 may be disposed on the third gate insulating film 133. The third gate metal layer GTL3 may include the second gate electrode G2 of the second thin film transistor TFT2. The second gate electrode G2 may overlap the second active layer ACT2 in the third direction DR3. The third gate metal layer GTL3 may be formed as a single layer or multiple layers of molybdenum (Mo), aluminium (Al), chromium (Cr), gold (Au), titanium (Ti), nickel (Ni), neodymium (Nd), and/or copper (Cu), and/or an alloy thereof.

A second interlayer insulating film 142 may be disposed on the second gate electrode G2 of the second thin film transistor TFT2 and the third gate insulating film 133. The second interlayer insulating film 142 may be formed of an inorganic film, for example, a silicon nitride film, a silicon oxynitride film, a silicon oxide film, a titanium oxide film, and/or an aluminium oxide film.

A first data metal layer DTL1 may be disposed on the second interlayer insulating film 142. The first data metal layer DTL1 may include a first source connection electrode SBE3, a second source connection electrode SBE1, and a third source connection electrode SBE2. The first source connection electrode SBE3 may be connected to the first drain area D1 of the first active layer ACT1 through a first source contact hole PCT1 penetrating a first gate insulating film 131, a second gate insulating film 132, a first interlayer insulating film 141, a third gate insulating film 133, and a second interlayer insulating film 142. A second source connection electrode SBE1 may be connected to the second source area S2 of the second active layer ACT2 through the second source connection contact hole BCT1 penetrating the second interlayer insulating film 142 and the third gate insulating film 133. The third source connection electrode SBE2 may be connected to the second drain area D2 of the second active layer ACT2 through the third source connection contact hole BCT2 penetrating the second interlayer insulating film 142 and the third gate insulating film 133. The first data metal layer DTL1 may be formed as a single layer or multiple layers of molybdenum (Mo), aluminium (Al), chromium (Cr), gold (Au), titanium (Ti), nickel (Ni), neodymium (Nd), and/or copper (Cu), and/or an alloy thereof. For example, the first data metal layer DTL1 may include a first layer made of titanium (Ti), a second layer made of aluminum (Al), and a third layer made of titanium (Ti).

A first organic film 160 may be disposed to flatten the step due to the first thin film transistor TFT1 and the second thin film transistor TFT2 on the first source connection electrode SBE3, the second source connection electrode SBE1, and the third source connection electrode SBE2, and on the second interlayer insulating film 142. The first organic layer 160 may be formed from an organic film such as acrylic resin, epoxy resin, phenolic resin, polyamide resin, polyimide resin, and/or the like.

A second data metal layer DTL2 may be disposed on the first organic film 160. The second data metal layer DTL2 may include a fourth source connection electrode SBE4. The fourth source connection electrode SBE4 may be connected to the first source connection electrode SBE3 through a second pixel contact hole PCT2 penetrating the first organic film 160. The second data metal layer DTL2 may be formed as a single layer or multiple layers of molybdenum (Mo), aluminium (Al), chromium (Cr), gold (Au), titanium (Ti), nickel (Ni), neodymium (Nd), and/or copper (Cu), and/or an alloy thereof. For example, the second data metal layer DTL2 may include a first layer made of titanium (Ti), a second layer made of aluminum (Al), and a third layer made of titanium (Ti).

A second organic film 180 may be disposed on the fourth source connection electrode SBE4 and the first organic film 160. The second organic film 180 may be formed of an organic film such as acrylic resin, epoxy resin, phenolic resin, polyamide resin, polyimide resin, and/or the like.

A light emitting element layer EML may be disposed on the second organic film 180. The light emitting element layer EML may include pixel electrodes PXE1, PXE2, and PXE3, light emitting elements LE, a common electrode CE, a connection electrode BE, and a bank 190.

A pixel electrode layer PXL may be disposed on the second organic film 180. The pixel electrode layer PXL may include a first pixel electrode PXE1, a second pixel electrode PXE2, and a third pixel electrode PXE3. In the first sub-pixel SPX1, the first pixel electrode PXE1 may be connected to the fourth source connection electrode SBE4 through a first connection hole (CT1 in FIG. 6) penetrating the second organic film 180. In the second sub-pixel SPX2, the second pixel electrode PXE2 may be connected to the fourth source connection electrode SBE4 through a second connection hole (CT2 in FIG. 6) penetrating the second organic film 180. In the third sub-pixel SPX3, the third pixel electrode PXE3 may be connected to the fourth source connection electrode SBE4 through a third connection hole (CT3 in FIG. 6) penetrating the second organic film 180.

In the first sub-pixel SPX1, the first pixel electrode PXE1 may be connected to the first source area S1 or the first drain area D1 of the first thin film transistor TFT1 through the first source connection electrode SBE3 and the fourth source connection electrode SBE4. Therefore, a voltage controlled by the first thin film transistor TFT1 in the first sub-pixel SPX1 may be applied to the first pixel electrode PXE1.

In addition, in the second sub-pixel SPX2, the second pixel electrode PXE2 may be connected to the first source area S1 or the first drain area D1 of the first thin film transistor TFT1 through the first source connection electrode SBE3 and the fourth source connection electrode SBE4. Therefore, a voltage controlled by the first thin film transistor TFT1 in the second sub-pixel SPX2 may be applied to the second pixel electrode PXE2.

Further, in the third sub-pixel SPX3, the third pixel electrode PXE3 may be connected to the first source area S1 or the first drain area D1 of the first thin film transistor TFT1 through the first source connection electrode SBE3 and the fourth source connection electrode SBE4. Therefore, a voltage controlled by the first thin film transistor TFT1 in the third sub-pixel SPX3 may be applied to the third pixel electrode PXE3.

The pixel electrode layer PXL may be formed as a single layer or multiple layers of molybdenum (Mo), aluminium (Al), chromium (Cr), gold (Au), titanium (Ti), nickel (Ni), neodymium (Nd), and/or copper (Cu), and/or an alloy thereof. For example, the pixel electrode layer PXL may be formed of a multilayer of copper (Cu) or an alloy of titanium (Ti) and copper (Cu), which has a low surface resistance to lower the resistance of each of the first pixel electrode PXE1, the second pixel electrode PXE2, and the third pixel electrode PXE3.

The bank 190 may be disposed between the first pixel electrode PXE1, the second pixel electrode PXE2, and the third pixel electrode PXE3. The bank 190 may be formed of an organic film such as acrylic resin, epoxy resin, phenolic resin, polyamide resin, polyimide resin, and/or the like. The bank 190 may include a light blocking material to prevent light from the light emitting element LE of one sub-pixel from proceeding to the neighboring sub-pixel. For example, the bank 190 may include an inorganic black pigment such as carbon black or an organic black pigment.

A plurality of light emitting elements LE may be disposed on the pixel electrode layer PXL. FIG. 7 illustrates that each of the plurality of light emitting elements LE is a vertical type micro LED extending in the third direction DR3. That is, the length of the light emitting element LE in the third direction DR3 may be greater than the length in the horizontal direction. The length in the horizontal direction refers to the length of the first direction DR1 and/or the length of the second direction DR2. For example, the length of the light emitting element LE in the third direction DR3 may be approximately 5 μm to 5.5 μm but is not limited thereto. However, the present disclosure is not limited to this, and the length of the light emitting element LE in the third direction DR3 may be equal to or less than the length in the horizontal direction in one or more other embodiments.

The light emitting element LE may have a cylindrical shape, a disk shape, or a rod shape where a width is longer than a height. However, it is not limited to this, and the light emitting element LE may have a shape such as a rod, wire, or tube, a polyhedron shape such as a cube, a cuboid, a hexagonal prism, or a shape that extends in one direction but has a partially sloped outer surface.

Each of the plurality of light emitting elements LE may be formed of an inorganic material such as gallium nitride (GaN). Each of the plurality of light emitting elements LE may have a length of several to hundreds of μm in the first direction DR1, a length in the second direction DR2, and a length in the third direction DR3. For example, each of the plurality of light emitting elements LE may have a length in the first direction DR1, a length in the second direction DR2, and a length in the third direction DR3 of approximately 100 μm or less.

Each of the plurality of light emitting elements LE may be formed by growing on a semiconductor substrate such as a silicon substrate and/or sapphire substrate. The plurality of light emitting elements LE may be directly transferred from the semiconductor substrate onto the pixel electrodes PXE1, PXE2, and PXE3 of the display panel 100. Alternatively, the plurality of light emitting elements LE may be transferred onto the pixel electrodes PXE1, PXE2, and PXE3 of the display panel 100 by an electrostatic method using an electrostatic head or by a stamp method using an elastic polymeric material such as PDMS and/or silicon as a transfer substrate.

The light emitting element LE may include a contact electrode CTE, a first semiconductor layer SEM1, an active layer MQW, a second semiconductor layer SEM2, a third semiconductor layer SEM3, and a protective layer INL. A vertical type micro LED refers to an LED having a structure in which a first semiconductor layer SEM1, an active layer MQW, a second semiconductor layer SEM2, and a third semiconductor layer SEM3, are sequentially arranged in the third direction DR3, which is the vertical direction.

The contact electrode CTE may be disposed on the pixel electrode layer PXL. The contact electrode CTE may be disposed on the entire lower surface of the first semiconductor layer SEM1 and at least a portion of the side surface of the light emitting element LE. Further, the contact electrode CTE may be disposed on the protective layer INL disposed on the side of the light emitting element LE. The contact electrode CTE may include molybdenum (Mo), aluminium (Al), chromium (Cr), gold (Au), titanium (Ti), nickel (Ni), neodymium (Nd), and/or copper (Cu).

The contact electrode CTE may be electrically connected to the first semiconductor layer SEM1.

The first semiconductor layer SEM1 may be disposed on the contact electrode CTE. A length of the bottom surface of the first semiconductor layer SEM1 in the first direction DR1 or the length in the second direction DR2 may be less than the length of the contact electrode CTE in the first direction DR1 or the length in the second direction DR2. The first semiconductor layer SEM1 may be made of GaN doped with a first conductive type dopant such as Mg, Zn, Ca, Sr, Ba, and/or the like.

The active layer MQW may be disposed on the first semiconductor layer SEM1. The active layer MQW may emit light by combining electron-hole pairs according to an electrical signal applied through the first semiconductor layer SEM1 and the second semiconductor layer SEM2.

The active layer MQW may include a material having a single or multi-quantum well structure. When the active layer MQW includes a material having a multi-quantum well structure, it may have a structure in which a plurality of well layers and barrier layers are alternately stacked. In this case, the well layer may be formed of InGaN, and the barrier layer may be formed of GaN or AlGaN but is not limited thereto. Alternatively, the active layer MQW may have a structure in which semiconductor materials having a high energy band gap and semiconductor materials having a low energy band gap are alternately stacked with each other, may include other Group Ill to V semiconductor materials according to the wavelength range of emitted light.

When the active layer MQW includes InGaN, the color of the emitted light may vary depending on the content of indium (In). For example, as the content of indium (In) increases, the wavelength band of light emitted by the active layer may shift to the red wavelength band, and as the content of indium (In) decreases, the wavelength band of light emitted by the active layer may shift to the blue wavelength band. For example, the content of indium (In) in the active layer MQW of the light emitting element LE that emits the third light (e.g., light in the blue wavelength band) may be approximately 10 wt % to 20 wt %.

The electron blocking layer may be disposed between the first semiconductor layer SEM1 and the active layer MQW. The electron blocking layer may be a layer to suppress or prevent too many electrons from flowing into the active layer MQW. For example, the electron blocking layer may be AlGaN and/or P-AlGaN doped with P-type Mg. The electron blocking layer may be omitted. The second semiconductor layer SEM2 may be disposed on the active layer MQW. The second semiconductor layer SEM2 may be doped with a second conductivity type dopant such as Si, Ge, Se, Sn, and/or the like. For example, the second semiconductor layer SEM2 may be N—GaN doped with N-type Si.

The superlattice layer may be disposed between the active layer MQW and the second semiconductor layer SEM2. The superlattice layer may be a layer for relieving stress between the second semiconductor layer SEM2 and the active layer MQW. For example, the superlattice layer may be formed of InGaN and/or GaN. The superlattice layer may be omitted. When the superlattice layer is disposed on the active layer MQW, the superlattice layer may be included in a first element rod LD1.

The third semiconductor layer SEM3 may be an undoped semiconductor. The third semiconductor layer SEM3 may include the same material as the second semiconductor layer SEM2 but may be a material that is not doped with an N-type or P-type dopant. In one or more embodiments, the third semiconductor layer SEM3 may be undoped InAlGaN, GaN, AlGaN, InGaN, AlN, and/or InN, but is not limited thereto.

In one or more embodiments, a current spreading layer may be further disposed on the first semiconductor layer SEM1. The current spreading layer may be made of a transparent conductive material (TCO) such as indium tin oxide (ITO) and/or indium zinc oxide (IZO) that may transmit light.

The first semiconductor layer SEM1, the active layer MQW, and the second semiconductor layer SEM2 of the light emitting element LE may be referred to as the first element rod LD1.

The element rod LD may include a first element rod LD1, a second element rod LD2, and a third element rod LD3, which are classified according to a change in the inclination angle of the side.

The first element rod LD1 may include a first sidewall SS1 having a first inclination angle θ1. The first inclination angle θ1 of the first side wall SS1 may be formed at 90 degrees as shown in FIG. 8A but is not limited thereto. For example, the first inclination angle θ1 may be greater than 70 degrees and less than 90 degrees. The first inclination angle θ1 is an angle an extension of the contact surface of the first element rod LD1 and the second element rod LD2 and a first sidewall SS1 of the first element rod LD1.

The first element rod LD1 may have a height in the range of from 0.3 μm to 0.5 μm but is not limited thereto.

The height h1 of the first element rod LD1 may be the lowest from among the first element rod LD1, the second element rod LD2, and the third element rod LD3. That is, the height h1 of the first element rod LD1 is less than the height of the second element rod LD2 and less than the height h2 of the third element rod LD3.

The second element rod LD2 is disposed on the first element rod LD1.

The second element rod LD2 may include a second sidewall SS2 having a second inclination angle θ2. The second inclination angle θ2 of the second side wall SS2 may be greater than 60 degrees and less than or equal to 80 degrees. Further, the second inclination angle θ2 may be less than the first inclination angle θ1. Therefore, the second side wall SS2 may be formed as a regular taper. The second element rod LD2 becomes wider towards the top, i.e. towards the third element rod LD3. The second inclination angle θ2 is an angle between an extension of the contact surface of the second element rod LD2 and the third element rod LD3 and the second sidewall SS2 of the second element rod LD2.

As shown in FIG. 8A, the side surfaces of the first element rod LD1 and the second element rod LD2 may be inconsistent with each other and may have a step difference but are not limited to this. As shown in FIG. 8B, the side surfaces of the first element rod LD1 and the second element rod LD2 may be aligned and coincide with each other.

The second element rod LD2 may include the second semiconductor layer SEM2.

The third element rod LD3 may be disposed on the second element rod LD2. The third element rod LD3 may include a third sidewall SS3 having a third inclination angle θ3. The third inclination angle θ3 of the third side wall SS3 may be formed at 90 degrees as shown in FIG. 8A but is not limited thereto. For example, the third inclination angle θ3 may be greater than 70 degrees and less than 90 degrees.

The third element rod LD3 may include a portion of the second semiconductor layer SEM2 and the third semiconductor layer SEM3.

The protective layer INL may be disposed on one surface and a side surface of the element rod LD. The protective layer INL may include a plurality of insulating layers INS1 and INS2 and a first reflective layer RF1.

The plurality of insulating layers INS1 and INS2 may include a first insulating layer INS1 and a second insulating layer INS2.

The first insulating layer INS1 may be disposed to be around (e.g., to surround) the first side wall SS1 and the second side wall SS2 of the element rod LD and one surface LD-B of the element rod LD. The first insulating layer INS1 may include a first opening OP1 exposing the first semiconductor layer SEM1 on one surface LD-B of the element rod LD.

The first insulating layer INS1 may be formed of an inorganic film, for example, a silicon nitride film, a silicon oxy nitride film, a silicon oxide film, a titanium oxide film, and/or an aluminum oxide film.

The first reflective layer RF1 may include a side wall reflective portion RF-W disposed to be around (e.g., to surround) a first side wall SS1 of the first element rod LD1 and a second side wall SS2 of the second element rod LD2 on the first insulating layer INS1, and a bottom reflective portion RF-B disposed on one surface LD-B of the element rod LD. The side wall reflective portion RF-W and the bottom reflective portion RF-B of the first reflective layer RF1 may be formed integrally.

The top of the side wall reflective portion RF-W may be formed to become thinner toward the top.

The bottom reflective portion RF-B may be formed to extend from the bottom of the side wall reflective portion RF-W and to cover one surface LD-B of the element rod LD. That is, the first reflective layer RF1 may cover the one surface LD-B and a portion of the side surface of the element rod LD. Alternatively, the first reflective layer RF1 may cover the entire area except the other surface LD-T opposite the one surface LD-B of the element rod LD. However, the bottom reflective portion RF-B may have a second opening OP2 that overlaps the first opening OP1. The width of the second opening OP2 may be wider than the width of the first opening OP1.

The first reflective layer RF1 allows light emitted from the element rod LD to exit upward. In particular, the second inclination angle θ2 of the second element rod LD2 disposed on the top of the first element rod LD1 is formed to be smaller than the first inclination angle θ1 of the first element rod LD1, so the light gathering efficiency toward the top may be improved. The first reflective layer RF1 may use omni-directional reflectors (ODR) but is not limited thereto. The omni-directional reflector ODR refers to a reflector that maintains high reflectivity over a wide wavelength range and wide angle of incidence. The first reflective layer RF1 may have a reflectivity of 90% or more in the visible range and may have a thickness of about 5 nm or more.

The height h2 of the second element rod LD2 on which the first reflective layer RF1 is disposed may have a range of about 2.0 μm to 2.3 μm but is not limited thereto. The height h2 of the second element rod LD2 on which the first reflective layer RF1 is disposed may be about four times the height h1 of the first element rod LD1 but is not limited thereto.

The height of the element rod LD without the first reflective layer RF1 disposed thereon may have a range of about 2.1 μm to 2.6 μm but is not limited thereto.

The second insulating layer INS2 may be disposed on a side of the element rod LD on the first reflective layer RF1 as an insulating layer to protect the first reflective layer RF1. The second insulating layer INS2 may be disposed on one surface LD-B of the first element rod LD1. The second insulating layer INS2 may have a third opening OP3 that overlaps the first opening OP1 and the second opening OP2. In one or more embodiments, the width of the third opening OP3 may be wider than the width of the first opening OP1 and narrower than the width of the second opening OP2. However, in one or more other embodiments, the width of the third opening OP3 may be wider than the width of the first opening OP1 and the width of the second opening OP2. Accordingly, the second insulating layer INS2 may be around (e.g., may surround) the second opening OP2 defined by the first reflective layer RF1. The first reflective layer RF1 may be covered by the second insulating layer INS2.

A contact electrode CTE may be in contact with the first semiconductor layer SEM1 through the first opening OP1, the second opening OP2, and the third opening OP3 penetrating the first insulating layer INS1, the first reflective layer RF1, and the second insulating layer INS2. The second insulating layer INS2 may be formed of aluminum oxide (Al₂O₃) but is not limited thereto. For example, the second insulating layer INS2 may be formed of an inorganic film, such as a silicon nitride film, a silicon oxynitride film, a silicon oxide film, a titanium oxide film, and/or an aluminum oxide film, the same as the first insulating layer INS1.

The first reflective layer RF1 may be completely surrounded by the second insulating layer INS2 and the first insulating layer INS1. Accordingly, the first reflective layer RF1 may be electrically disconnected from the element rod LD.

The connection electrode BE connects the contact electrode CTE of the light emitting element LE with the first pixel electrode PXE1, the second pixel electrode PXE2, or the third pixel electrode PXE3. The connection electrode BE may be disposed on the top surface of the first pixel electrode PXE1, the second pixel electrode PXE2, or the third pixel electrode PXE3 on which the light emitting element LE is not disposed. Further, the connection electrode BE may be disposed on a side of the contact electrode CTE. Additionally, the connection electrode BE may be disposed on a portion of the side surface of the light emitting element LE. For example, the connection electrode BE may be disposed on the side of the first element rod LD1 of the light emitting element LE and on at least a portion of the second element rod LD2.

The connection electrode BE may include molybdenum (Mo), aluminum (Al), chromium (Cr), gold (Au), titanium (Ti), nickel (Ni), neodymium (Nd), and/or copper (Cu). Alternatively, the connection electrode BE may be made of a transparent conductive material (TCO) such as indium tin oxide (ITO) and/or indium zinc oxide (IZO) that may transmit light.

When the connection electrode BE is made of a highly reflective metal material such as aluminum (Al), light emitted from the active layer MQW of the light emitting element LE that proceeds in the side direction of the light emitting element LE may be reflected from the connection electrode BE and proceed in the upper direction of the light emitting element LE. Therefore, because light loss from the light emitting element LE may be reduced, the light efficiency of the light emitting element LE may be increased. The connection electrode BE may be formed as a single layer of a highly reflective metal, or may be formed as a multilayer, such as titanium (Ti)/aluminum (Al)/titanium (Ti) and/or ITO/aluminum (Al)/ITO.

A third organic film 191 may be disposed to cover the bank 190 and a portion of the side surfaces of the plurality of light emitting elements LE. Further, the third organic film 191 may be disposed to cover the connection electrode BE, but at least a portion of the connection electrode BE may be exposed without being covered by the third organic film 191. The third organic film 191 may be formed of an organic film such as acrylic resin, epoxy resin, phenolic resin, polyamide resin, polyimide resin, and/or the like.

A fourth organic film 192 may be disposed on the third organic film 191. The fourth organic film 192 may be disposed to cover a portion of the side surface of each of the plurality of light emitting elements LE. The fourth organic film 192 may be disposed over at least a portion of the second element rod LD2 that is exposed and not covered by the third organic film 191 and at least a portion of the third element rod LD3. The top surface of each of the plurality of light emitting elements LE may be exposed without being covered by the fourth organic film 192. The fourth organic film 192 may be formed of an organic film such as acrylic resin, epoxy resin, phenolic resin, polyamide resin, and polyimide resin, and/or the like.

The third organic film 191 and the fourth organic film 192 are layers for flattening steps caused by the plurality of light emitting elements LE. When the height of the third organic film 191 is arranged to cover most of the side surfaces of each of the plurality of light emitting elements LE, the fourth organic film 192 may be omitted.

The common electrode CE may be disposed on the top surface of each of the plurality of light emitting elements LE and on the top surface of the fourth organic film 192. The common electrode CE may be a common layer commonly formed in the first sub-pixel SPX1, the second sub-pixel SPX2, and the third sub-pixel SPX3. The common electrode CE may be made of a transparent conductive material (TCO) such as indium tin oxide (ITO) and/or indium zinc oxide (IZO) that may transmit light.

In one or more embodiments, the pixel electrode PXE (PXE1, PXE2, PXE3) may be referred to as an anode electrode or a first electrode, and the common electrode CE may be referred to as a cathode electrode or a second electrode.

The first capping layer CAP1 may be disposed on the common electrode CE. The first capping layer CAP1 may be formed of an inorganic film, for example, a silicon nitride film, a silicon oxy nitride film, a silicon oxide film, a titanium oxide film, and/or an aluminum oxide film.

A light blocking layer BM, a first light conversion layer QDL1, a second light conversion layer QDL2, and a light transmission layer TPL may be disposed on the first capping layer CAP1. However, the present disclosure is not limited thereto, and a third light conversion layer may be disposed instead of the light transmission layer TPL. In this case, the third light conversion layer may include a material different from the first light conversion layer QDL1 and the second light conversion layer QDL2. For example, the first light conversion layer QDL1 may include quantum dots that convert light in a blue wavelength band into light in a red wavelength band, and the second light conversion layer QDL2 may include quantum dots that convert light in a blue wavelength band to light in a green wavelength band, and the third light conversion layer may include a blue phosphor. Additionally, each of the first light conversion layer QDL1, the second light conversion layer QDL2, and the third light conversion layer may include a light diffuser such as titanium dioxide (TiO₂) in addition to quantum dots. In this case, the number of titanium dioxide (TiO₂) particles in the third light conversion layer may be greater than the number of titanium dioxide (TiO₂) particles in the first light conversion layer QDL1 or the number of titanium dioxide (TiO₂) particles in the second light conversion layer QDL2.

The first light conversion layer QDL1, the second light conversion layer QDL2, and the light transmission layer TPL may be partitioned by the light blocking layer BM. Therefore, the first light conversion layer QDL1 may be disposed on the first capping layer CAP1 in the first sub-pixel SPX1, and the second light conversion layer QDL2 may be disposed on the first capping layer CAP1 in the second sub-pixel SPX2, and the light transmission layer TPL may be disposed on the first capping layer CAP1 in the third sub-pixel SPX3. The light blocking layer BM may overlap the bank 190 in the third direction DR3 and may not overlap the plurality of light emitting elements LE.

The first light conversion layer QDL1 may convert a portion of the third light (e.g., light in the blue wavelength band) incident from the light emitting element LE into first light (e.g., light in the red wavelength band). The first light conversion layer QDL1 may include a first base resin BRS1 and first wavelength conversion particles WCP1. The first base resin BRS1 may include a light transmission organic material. For example, the first base resin BRS1 may include an epoxy-based resin, an acrylic-based resin, a cado-based resin, and/or an imide-based resin. The first wavelength conversion particle WCP1 may convert a portion of the third light (e.g., light in the blue wavelength band) incident from the light emitting element LE into first light (e.g., light in the red wavelength band). The first wavelength conversion particle WCP1 may be a quantum dot (QD), a quantum rod, a fluorescent material, and/or a phosphorescent material. The first light conversion layer QDL1 may further include a light diffusion agent such as titanium dioxide (TiO₂).

The second light conversion layer QDL2 may convert a portion of the third light (e.g., light in the blue wavelength band) incident from the light emitting element LE into second light (e.g., light in the green wavelength band). It may include a second base resin BRS2 and a second wavelength conversion particle WCP2. The second base resin BRS2 may include a light transmission organic material. For example, the second base resin BRS2 may include an epoxy-based resin, an acrylic-based resin, a cado-based resin, and/or an imide-based resin. The second wavelength conversion particle WCP2 may convert a portion of the third light (e.g., light in the blue wavelength band) incident from the light emitting element LE into second light (e.g., light in the green wavelength band). The second wavelength conversion particle WCP2 may be a quantum dot (QD), a quantum rod, a fluorescent material, and/or a phosphorescent material. The second light conversion layer QDL2 may further include a light diffusion agent such as titanium dioxide (TiO₂).

The light transmission layer TPL may include a light transmission organic material. For example, the light transmission layer TPL may include epoxy resin, acrylic resin, cardo resin, and/or imide resin.

The light blocking layer BM may include a first light blocking layer BM1 and a second light blocking layer BM2 that are sequentially stacked. A length in the first direction DR1 or a length in the second direction DR2 of the first light blocking layer BM1 may be wider than a length in the first direction DR1 or a length in the second direction DR2 of the second light blocking layer BM2. The length (or height) in the third direction DR3 of the first light blocking layer BM1 may be greater than the length (or height) in the third direction DR3 of the second light blocking layer BM2. The first light blocking layer BM1 and the second light blocking layer BM2 may include an organic film formed from acrylic resin, epoxy resin, phenolic resin, polyamide resin, polyimide resin, and/or the like. For example, the first light blocking layer BM1 and the second light blocking layer BM2 may include an inorganic black pigment such as carbon black and/or an organic black pigment.

The second capping layer CAP2 may be disposed on the first capping layer CAP1 and the light blocking layer BM. The second capping layer CAP2 may be disposed on the side and top surfaces of the light blocking layer BM. That is, the second capping layer CAP2 may be disposed on the side of the first light blocking layer BM1 and on the side and top surfaces of the second light blocking layer BM2. The second capping layer CAP2 serves to protect the first wavelength conversion particles WCP1 of the first light conversion layer QDL1 and the second wavelength conversion particles WCP2 of the second light conversion layer QDL2 from moisture penetration, and thus, in one or more embodiments, may be arranged to be around (e.g., to surround) the top, bottom, and side(s) of the first light conversion layer QDL1 and the second light conversion layer QDL2.

The second reflective layer RF2 may be disposed between the light blocking layer BM and the first light conversion layer QDL1, between the light blocking layer BM and the second light conversion layer QDL2, and between the light blocking layer BM and the light transmission layer TPL. The second reflective layer RF2 may be disposed on the second capping layer CAP2 disposed on the side of the first light blocking layer BM1 and the side of the second light blocking layer BM2. The second reflective layer RF2 serves to reflect light traveling in the lateral direction from the first light conversion layer QDL1, the second light conversion layer QDL2, and the light transmission layer TPL.

The second reflective layer RF2 may include a highly reflective metal material such as aluminum (Al). The thickness of the second reflective layer RF2 may be approximately 0.1 μm.

Alternatively, the second reflective layer RF2 may include M (where M is an integer greater than or equal to 2) pairs of first and second layers having different refractive indices to act as Distributed Bragg Reflectors (DBR). In this case, M first layers and M second layers may be arranged alternately. The first layer and the second layer may be formed of an inorganic film, for example, a silicon nitride film, a silicon oxy nitride film, a silicon oxide film, a titanium oxide film, and/or an aluminum oxide film.

The third capping layer CAP3 may be disposed on the second capping layer CAP2, the first light conversion layer QDL1, the second light conversion layer QDL2, and the light transmission layer TPL. The third capping layer CAP3 may be formed of an inorganic film, for example, a silicon nitride film, a silicon oxynitride film, a silicon oxide film, a titanium oxide film, or an aluminium oxide film. The first light conversion layer QDL1, the second light conversion layer QDL2, and the light transmission layer TPL may be encapsulated by the first capping layer CAP1, the second capping layer CAP2, and the third capping layer CAP3. The refractive index of the third capping layer CAP3 may be lower than the refractive index of the second capping layer CAP2. Further, the refractive index of the third capping layer CAP3 may be lower than the refractive index of a fifth organic film 193.

The fifth organic film 193 may be disposed on the third capping layer CAP3. The fifth organic film 193 may be formed of acrylic resin, epoxy resin, phenolic resin, polyamide resin, polyimide resin, and/or the like.

A plurality of color filters CF1, CF2, and CF3 may be disposed on the fifth organic film 193. The plurality of color filters CF1, CF2, and CF3 may include first color filters CF1, second color filters CF2, and third color filters CF3. However, the present disclosure is not limited to this. When the light emitting elements LE of the first sub-pixel SPX1 emit light of a first color, and the light emitting elements LE of the second sub-pixel SPX2 emit light of a second color, and the light emitting element LE of the third sub-pixel SPX3 emits light of a third color, the first light conversion layer QDL1, the second light conversion layer QDL2, the light transmission layer TPL, and the light blocking layer BM may be omitted, the fifth organic film 193 is disposed on the common electrode CE, and the plurality of color filters CF1, CF2, and CF3 are disposed on the fifth organic film 193 or the plurality of color filters CF1, CF2, and CF3 may be omitted.

The first color filter CF1 disposed in the first sub-pixel SPX1 may transmit the first light (e.g., light in the red wavelength band) and absorb or block the third light (e.g., light in the blue wavelength band). Therefore, the first color filter CF1 may transmit the first light (e.g., light in the red wavelength band) converted by the first light conversion layer QDL1 from among the third light (e.g., light in the blue wavelength band) emitted by the light emitting element LE and absorb or block the third light (e.g., light in the blue wavelength band) not converted by the first light conversion layer QDL1. Thus, the first sub-pixel SPX1 may emit the first light (e.g., light in the red wavelength band).

The second color filter CF2 disposed in the second sub-pixel SPX2 may transmit the second light (e.g., light in the green wavelength band) and absorb or block the third light (e.g., light in the blue wavelength band). Therefore, the second color filter CF2 may transmit the second light (e.g., light in the green wavelength band) converted by the second light conversion layer QDL2 from among the third light (e.g., light in the blue wavelength band) emitted by the light emitting element LE and absorb or block the third light (e.g., light in the blue wavelength band) not converted by the second light conversion layer QDL2. Thus, the second sub-pixel SPX2 may emit the second light (e.g., light in the green wavelength band).

The third color filter CF3 disposed in the third sub-pixel SPX3 may transmit third light (e.g., light in the blue wavelength band). Therefore, the third color filter CF3 may transmit the third light (e.g., light in the blue wavelength band) emitted from the light emitting element LE through the light transmission layer TPL. Accordingly, the third sub-pixel SPX3 may emit the third light (e.g., light in the blue wavelength band).

Each of the first to third color filters CF1, CF2, and CF3 serves to block external light incident from the outside. For example, the first color filter CF1 disposed in the first sub-pixel SPX1 may block the second light, which is light in the green wavelength band, and the third light, which is light in the blue wavelength band, incident from the outside, thereby increasing the purity (color purity) of the color corresponding to the first light, which is light in the red wavelength band.

The first color filter CF1, the second color filter CF2, and the third color filter CF3 overlapping in the third direction DR3 may overlap with the bank 190 and the light blocking layer BM in the third direction DR3.

A sixth organic film 194 for planarization may be disposed on the plurality of color filters CF1, CF2, and CF3. The sixth organic film 194 may be formed of acrylic resin, epoxy resin, phenolic resin, polyamide resin, polyimide resin, and/or the like.

According to FIGS. 7, 8A, and 8B, the light emitting element LE includes a first element rod LD1 having a first inclination angle θ1, a second element rod LD2 having a second inclination angle θ2, and a third element rod LD3 having a third inclination angle θ3. As a result, it is possible to secure a sufficient width of the active layer for the chip size while reducing or minimizing damage to the active layer during processing. This effect will be explained again in the description of the process described later.

In addition, by adopting a protective layer INL having a structure of a first insulating layer INS1, a first reflective layer RF1, and a second insulating layer INS2 disposed on the side of the light emitting element LE, the light emitted from the side of the light emitting element LE is directed upward, but the first reflective layer RF1 is formed to be surrounded by an insulator, so that the first reflective layer RF1 may be protected during subsequent processing.

Furthermore, because the contact electrode CTE is disposed on the protective layer INL disposed on the side of the first semiconductor layer SEM1, the contact area between the contact electrode CTE and the connection electrode BE may be increased. Therefore, the contact resistance between the contact electrode CTE and the connection electrode BE may be reduced, and the contact electrode CTE and the connection electrode BE may be more stably connected.

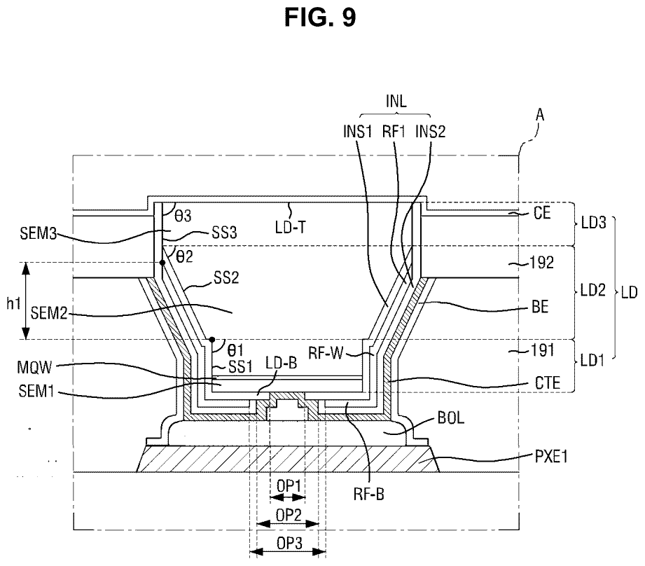

FIG. 9 is a cross-sectional view illustrating another example of the area A of FIG. 7 in detail.

The embodiment of FIG. 9 differs from the embodiment of FIGS. 8A and 8B in that an organic pattern layer BOL is disposed between the pixel electrode PXE and the light emitting element LE, and in the embodiment of FIG. 9, the description overlapping with the embodiments of FIGS. 8A and 8B will be omitted.

Referring to FIG. 9, an organic pattern layer BOL is disposed on a pixel electrode PXE, and a light emitting element LE is disposed on the organic pattern layer BOL.

The organic pattern layer BOL serves to temporarily fix or adhere the plurality of light emitting elements LE to prevent the plurality of light emitting elements LE from tilting or falling in the process of transferring the plurality of light emitting elements LE to the display panel 100. That is, the organic pattern layer BOL may be a membrane for temporarily adhering the plurality of light emitting elements LE on each of the first pixel electrode PXE1, the second pixel electrode PXE2, and the third pixel electrode PXE3. To facilitate temporary adhesion, the thickness of the organic pattern layer BOL may be greater than the thickness of each of the pixel electrodes PXE1, PXE2, and PXE3.

After the transfer process of the light emitting element LE is completed, the organic pattern layer BOL may be cured to form a robust bonding between the light emitting element LE and the organic pattern layer BOL. Unlike the eutectic process, which is a general bonding process, the bonding process using the organic pattern layer BOL does not require heat and pressure that may damage the light emitting element LE, so it has the effect of preventing the light emitting element LE from defects.

The organic pattern layer BOL may include an insulating material without electrical connection. Further, the organic pattern layer BOL may be a photosensitive organic layer such as photoresist. Alternatively, the organic pattern layer BOL may be formed of acrylic resin, epoxy resin, phenolic resin, polyamide resin, polyimide resin, and/or the like.

The light emitting element LE may be disposed on the organic pattern layer BOL.

The organic pattern layer BOL may be disposed narrower or wider than the light emitting element LE, but at least a portion of the pixel electrode PXE should be exposed. The connection electrode BE may be disposed on the exposed pixel electrode PXE on the side of the organic pattern layer BOL and the light emitting element LE. The connection electrode BE electrically connects the pixel electrode PXE and the contact electrode CTE.

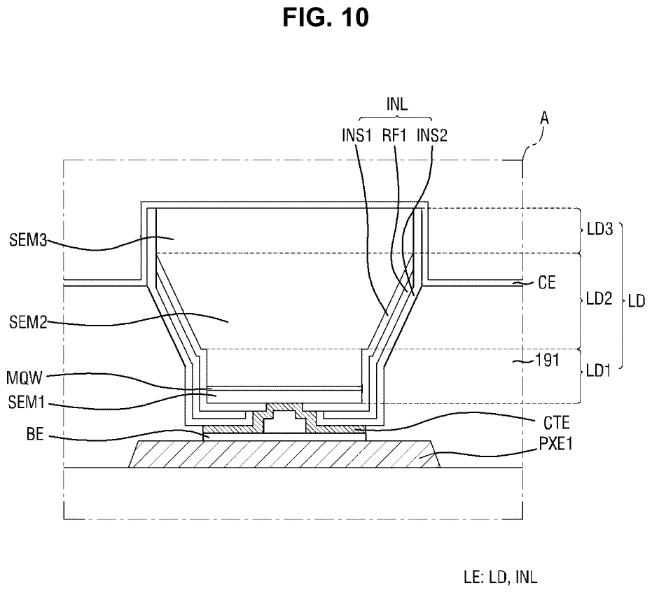

FIG. 10 is a cross-sectional view illustrating another example of the area A of FIG. 7 in detail.

The embodiment of FIG. 10 differs from the embodiment of FIGS. 8A-8B in that the connection electrode BE is disposed between the contact electrode CTE and the first pixel electrode PXE1, and in the embodiment of FIG. 10, the description overlapping with the embodiments of FIGS. 8A-8B will be omitted.

Referring to FIG. 10, the light emitting element LE and the first pixel electrode PXE1 may be bonded through electrostatic bonding. Accordingly, the connection electrode BE may be disposed between the contact electrode CTE and the first pixel electrode PXE1.

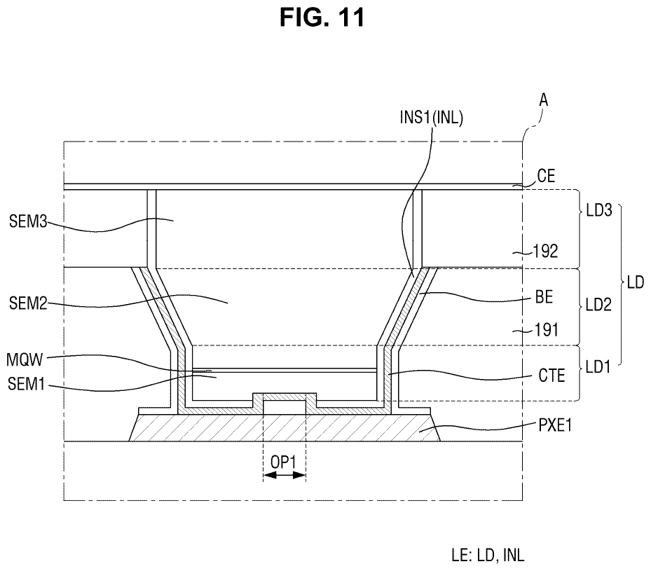

FIG. 11 is a cross-sectional view illustrating another example of area A of FIG. 7 in detail.

The embodiment of FIG. 11 differs from the embodiment of FIGS. 8A-8B in that the protective layer INL is composed of the first insulating layer INS1, and in the embodiment of FIG. 11, the description overlapping with the embodiment of FIGS. 8A-8B will be omitted.

Referring to FIG. 11, the protective layer INL may include a first insulating layer INS1.

The first insulating layer INS1 may be around (e.g., may surround) one surface and a side surface of the first element rod LD1, a side surface of the second element rod LD2, and a side surface of the third element rod LD3. The first insulating layer INS1 has a first opening OP1 penetrating the first insulating layer INS1 on one surface of the first element rod LD1. One surface of the first element rod LD1 may be exposed through the first opening OP1.

The contact electrode CTE may be disposed on the first element rod LD1 and the second element rod LE2 on the first insulating layer INS1. In one or more embodiments, the contact electrode CTE may be implemented to be disposed only on the first element rod LD1 on the first insulating layer INS1.

The contact electrode CTE may be electrically connected to the first element rod LD1 exposed through the first opening OP1.

The connection electrode BE may be disposed on one side of the first pixel electrode PXE1, which may be disposed on the side of the light emitting element LE along the contact electrode CTE.

As shown in FIG. 11, when the first reflective layer RF1 and the second insulating layer INS2 are omitted, the process may be simplified.

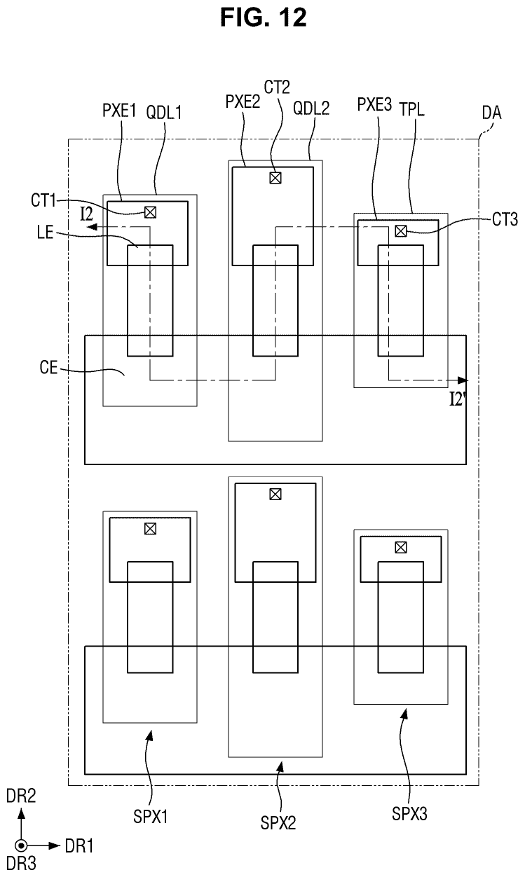

FIG. 12 is a layout diagram illustrating pixels of a display area according to one or more embodiments.

The embodiment of FIG. 12 differs from the embodiment of FIG. 6 in that each of the first sub-pixel SPX1, the second sub-pixel SPX2, and the third sub-pixel SPX3 includes a pixel electrode PXE1, PXE2, and PXE3 and a common electrode CE at both ends. In the embodiment of FIG. 12, descriptions overlapping with the embodiment of FIG. 6 will be omitted.

Referring to FIG. 12, each of the first pixel electrode PXE1, the second pixel electrode PXE2, and the third pixel electrode PXE3 may have a rectangular planar shape. Depending on the light conversion efficiency of the first light conversion layer QDL1 and the light conversion efficiency of the second light conversion layer QDL2, an area of the first sub-pixel SPX1, an area of the second sub-pixel SPX2, and an area of the third subpixel SPX3 may be set.

For example, as shown in FIG. 12, the area of the second pixel electrode PXE2 may be larger than the area of the first pixel electrode PXE1, and the area of the first pixel electrode PXE1 may be larger than the area of the third pixel electrode PXE3. Further, the first sub-pixel SPX1, the second sub-pixel SPX2, and the third sub-pixel SPX3 may include one common electrode CE in common.

The common electrode CE may be disposed in the first sub-pixel SPX1, the second sub-pixel SPX2, and the third sub-pixel SPX3 at a time when the first pixel electrode PXE1, the second pixel electrode PXE2, and the third pixel electrode PXE3 are not in place but is not limited thereto. In one or more embodiments, the common electrode CE may be provided in each of the first sub-pixel SPX1, the second sub-pixel SPX2, and the third sub-pixel SPX3.

In the first sub-pixel SPX1, the first pixel electrode PXE1 and the common electrode CE may be disposed to be spaced (e.g., spaced apart) from each other in the second direction DR2. In the second sub-pixel SPX2, the second pixel electrode PXE2 and the common electrode CE may be disposed to be spaced (e.g., spaced apart) from each other in the second direction DR2. In the third sub-pixel SPX3, the third pixel electrode PXE3 and the common electrode CE may be disposed to be spaced (e.g., spaced apart) from each other in the second direction DR2.

The first pixel electrode PXE1 may be connected to the second electrode of the fourth transistor (ST4 in FIGS. 4 and 5) and the second electrode of the sixth transistor (ST6 in FIGS. 4 and 5) of the first sub-pixel SPX1 through the first connection hole CT1. The second pixel electrode PXE2 may be connected to the second electrode of the fourth transistor (ST4 in FIGS. 4 and 5) and the second electrode of the sixth transistor (ST6 in FIGS. 4 and 5) of the second sub-pixel SPX2 through the second connection hole CT2. The third pixel electrode PXE3 may be connected to the second electrode of the fourth transistor (ST4 in FIGS. 4 and 5) and the second electrode of the sixth transistor (ST6 in FIGS. 4 and 5) of the third sub-pixel SPX3 through the third connection hole CT3.

The common electrode CE may be connected to the second power supply line VSL to which the second driving voltage VSS is applied through a connection hole (e.g., a fourth connection hole). Therefore, the second driving voltage VSS may be applied to the common electrode CE.

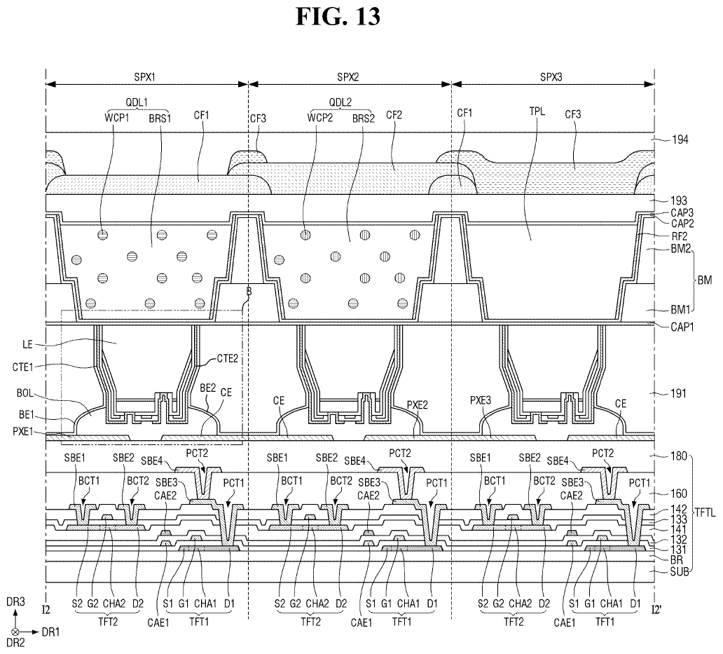

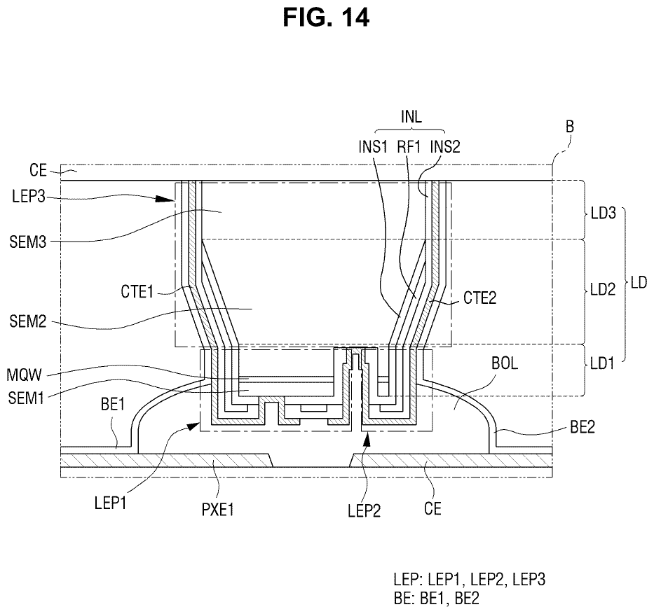

FIG. 13 is a cross-sectional view of a display panel corresponding to the line 12-12′ in FIG. 12. FIG. 14 is a cross-sectional view illustrating an example of an area B of FIG. 13 in detail.

The embodiments of FIGS. 13 and 14 differ from the embodiments of FIGS. 7 and 8 in that the light emitting element LE is a flip type micro LED. In the embodiments of FIGS. 13 and 14, descriptions overlapping with those of the embodiments of FIGS. 7 and 8 will be omitted.

Referring to FIGS. 13 and 14, the light emitting element LE may be a flip-type micro LED. The flip-type micro LED refers to an LED in which contact electrodes CTE1 and CTE2 are formed on one side (e.g., the bottom side) of the light emitting element LE. In one or more embodiments, contact electrodes CTE1 and CTE2 may be formed on the side surface of the light emitting element LE as well.

The pixel electrode layer PXL including the pixel electrodes PXE1, PXE2, and PXE3 and the common electrode CE may be disposed on the second organic film 180.

The light emitting element LE includes first to third portions LEP1, LEP2, and LEP3. The first portion LEP1 and the second portion LEP2 may be spaced (e.g., spaced apart) from each other. The third portion LEP3 may be connected to the first portion LEP1 and the second portion LEP2. The third portion LEP3 may be disposed on the first portion LEP1 and the second portion LEP2.

The first portion LEP1 includes a first contact electrode CTE1, a first semiconductor layer SEM1, an active layer MQW, a second semiconductor layer SEM2, and a protective layer INL. The second portion LEP2 includes a second contact electrode CTE2, the first semiconductor layer SEM1, the active layer MQW, a second semiconductor layer SEM2, and a protective layer INL, and the third portion LEP3 includes a second semiconductor layer SEM2, a third semiconductor layer SEM3, and a protective film INL. In one or more embodiments, the third portion LEP3 may also include the first contact electrode CTE1 and the second contact electrode CTE2.

The first semiconductor layer SEM1 may be disposed on the first contact electrode CTE1 (and the second contact electrode CTE2), the active layer MQW may be disposed on the first semiconductor layer SEM1, and the second semiconductor layer SEM2 may be disposed on the active layer MQW.

The third semiconductor layer SEM3 of the third portion LEP3 may be connected to the second semiconductor layer SEM2 of the first portion LEP1 and the second semiconductor layer SEM2 of the second portion LEP2. The second semiconductor layer SEM2 of the first portion LEP1, the second semiconductor layer SEM2 of the second portion LEP2, and the third semiconductor layer SEM3 of the third portion LEP3 may be formed integrally.

The first contact electrode CTE1 may be disposed on the bottom surface and outer surface of the first semiconductor layer SEM1. The second contact electrode CTE2 may be disposed on the bottom surface and outer surface of the first semiconductor layer SEM1 of the second portion LEP2. In one or more embodiments, first contact electrode CTE2 may be disposed on the outer surfaces of the first semiconductor layer SEM1, the active layer MQW, the second semiconductor layer SEM2, and the third semiconductor layer SEM3. In one or more embodiments, second contact electrode CTE1 may be disposed on the outer surfaces of the first semiconductor layer SEM1, the active layer MQW, the second semiconductor layer SEM2, and the third semiconductor layer SEM3. The first contact electrode CTE1 and the second contact electrode CTE2 may include molybdenum (Mo), aluminium (Al), chromium (Cr), gold (Au), titanium (Ti), nickel (Ni), neodymium (Nd), and/or copper (Cu).

The protective layer INL may be disposed on the outer surface of the first portion LEP1, the outer surface of the second portion LEP2, and the side surface of the third portion LEP3. Specifically, the protective layer INL may be disposed on the outer surface of the first semiconductor layer SEM1, the outer surface of the active layer MQW, and the outer surface of the second semiconductor layer SEM2 in the first portion LEP1. Further, the protective layer INL may be disposed on the outer surface of the first semiconductor layer SEM1, the active layer MQW, and the second semiconductor layer SEM2 in the second portion LEP2.

An organic pattern layer BOL may be disposed between each of the first pixel electrode PXE1, the second pixel electrode PXE2, and the third pixel electrode PXE3 and the common electrode CE. The organic pattern layer BOL temporarily fix or adhere the plurality of light emitting elements LE to prevent the plurality of light emitting elements LE from tilting or falling during the process of transferring the plurality of light emitting elements LE to the display panel 100. That is, the organic pattern layer BOL may be a membrane for temporarily adhering the plurality of light emitting elements LE on each of the first pixel electrode PXE1, the second pixel electrode PXE2, and the third pixel electrode PXE3. To facilitate temporary adhesion, the thickness of the organic pattern layer BOL may be greater than the thickness of each of the pixel electrodes PXE1, PXE2, and PXE3.

After the transfer process of the light emitting element LE is completed, the organic pattern layer BOL may be cured to form a robust bonding between the light emitting element LE and the organic pattern layer BOL. Unlike the eutectic process, which is a general bonding process, the bonding process using the organic pattern layer BOL does not require heat and pressure that may damage the light emitting element LE, so it has the effect of preventing the light emitting element LE from defects.

The organic pattern layer BOL may include an insulating material without electrical connection. Further, the organic pattern layer BOL may be a photosensitive organic layer such as photoresist. Alternatively, the organic pattern layer BOL may be formed of acrylic resin, epoxy resin, phenolic resin, polyamide resin, polyimide resin, and/or the like.

The light emitting element LE may be disposed on the organic pattern layer BOL. A first contact electrode CTE1 and a second contact electrode CTE2 may be disposed on the organic pattern layer BOL.

As shown in FIG. 13, the organic pattern layer BOL may be disposed wider than the width of the light emitting element LE.

The first connection electrode BE1 connects the first contact electrode CTE1 and the first pixel electrode PXE1, the second pixel electrode PXE2, or the third pixel electrode PXE3. The first connection electrode BE1 may be disposed on the top surface of the first pixel electrode PXE1, the second pixel electrode PXE2, and/or the third pixel electrode PXE3 that is exposed and not covered by the organic pattern layer BOL. Further, the first connection electrode BE1 may be disposed on the side of the organic pattern layer BOL and the side of the first contact electrode CTE1. Additionally, the first connection electrode BE1 may be disposed on the outer surface of the first portion LEP1 and the side surface of the third portion LEP3 of the light emitting element LE. The first connection electrode BE1 may be disposed on a portion of the protective layer INL of the light emitting element LE.

The second connection electrode BE2 connects the second contact electrode CTE2 and the common electrode CE. The second connection electrode BE2 may be disposed on an exposed top surface of the common electrode CE that is not covered by the organic pattern layer BOL. Further, the second connection electrode BE2 may be disposed on the side of the organic pattern layer BOL and the side of the second contact electrode CTE2. Additionally, the second connection electrode BE2 may be disposed on the outer side surface of the second portion LEP2 and the side surface of the third portion LEP3 of the light emitting element LE. The second connection electrode BE2 may be disposed on a portion of the protective layer INL of the light emitting element LE.

Each of the first connection electrode BE1 and the second connection electrode BE2 may include molybdenum (Mo), aluminium (Al), chromium (Cr), gold (Au), titanium (Ti), nickel (Ni), neodymium (Nd), and/or copper (Cu). Alternatively, each of the first connection electrode BE1 and the second connection electrode BE2 may be made of a transparent conductive material (TCO) such as indium tin oxide (ITO) and/or indium zinc oxide (IZO) that is capable of transmitting light.

When each of the first connection electrode BE1 and the second connection electrode BE2 is made of a highly reflective metal material such as aluminium (Al), light emitted from the active layer MQW of the light emitting element LE that proceeds in the side direction of the light emitting element LE may be reflected from the connection electrode BE (e.g., BE1, BE2) and proceed in the upward direction of the light emitting element LE. Therefore, the light loss of the light emitting element LE may be reduced, and the light efficiency of the light emitting element LE may be increased.

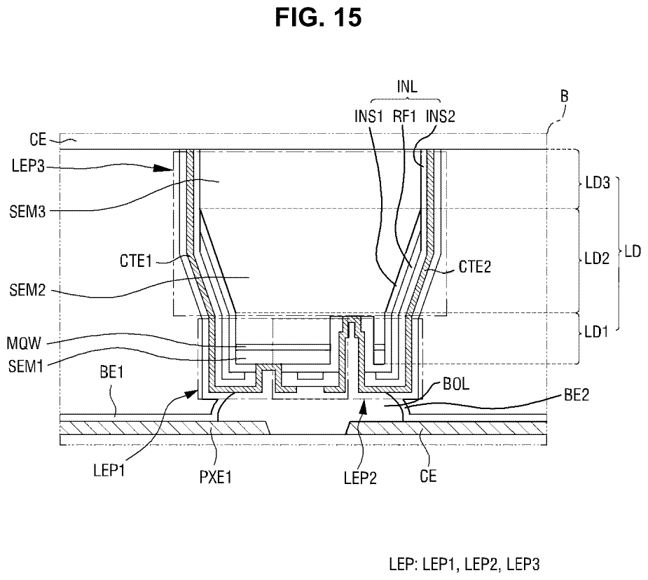

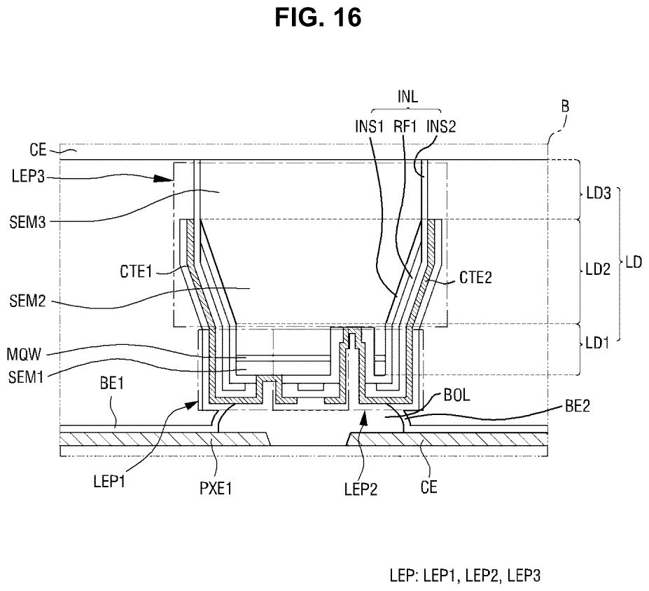

FIGS. 15 and 16 are cross-sectional views illustrating another example of the area B of FIG. 13 in detail.

The embodiments of FIGS. 15 and 16 differ from the embodiment of FIG. 14 in that the organic pattern layer BOL is formed narrower than the light emitting element LE, and in the embodiment of FIGS. 15 and 16, descriptions overlapping with the embodiment of FIG. 14. will be omitted.

Referring to FIGS. 15 and 16, because the side surfaces of the first contact electrode CTE1 and the second contact electrode CTE2 protrude from the side surfaces of the organic pattern layer BOL, a portion of the bottom surface of the first contact electrode CTE1 and the second contact electrode CTE2 may be exposed. As a result, the connection electrode BE may be disposed on the side surface of the organic pattern layer BOL and on a portion of the side surface and bottom surface of the first contact electrode CTE1 and the second contact electrode CTE2. Further, the width of the organic pattern layer BOL may be smaller than the width of the bottom surface of the light emitting element LE.

According to the embodiment of FIGS. 15 and 16, because the connection electrode BE is also in contact with a portion of the bottom surfaces of the first contact electrode CTE1 and the second contact electrode CTE2, the contact area between the first contact electrode CTE1 and the second contact electrode CTE2 and the connection electrode BE may be increased. Therefore, the contact resistance between the first contact electrode CTE1 and the second contact electrode CTE2 and the connection electrode BE may be reduced, and the connection between the first contact electrode CTE1 and the second contact electrode CTE2 and the connection electrode BE may be more stable.

Therefore, because the contact area between the connection electrode BE and the first contact electrode CTE1 and the second contact electrode CTE2 is sufficiently secured, the connection electrode BE and the first contact electrode CTE1 and the second contact electrode CTE2 may be disposed only on one side of the first element rod LD1 and on the side of the second element rod LD2, as shown in FIG. 16.

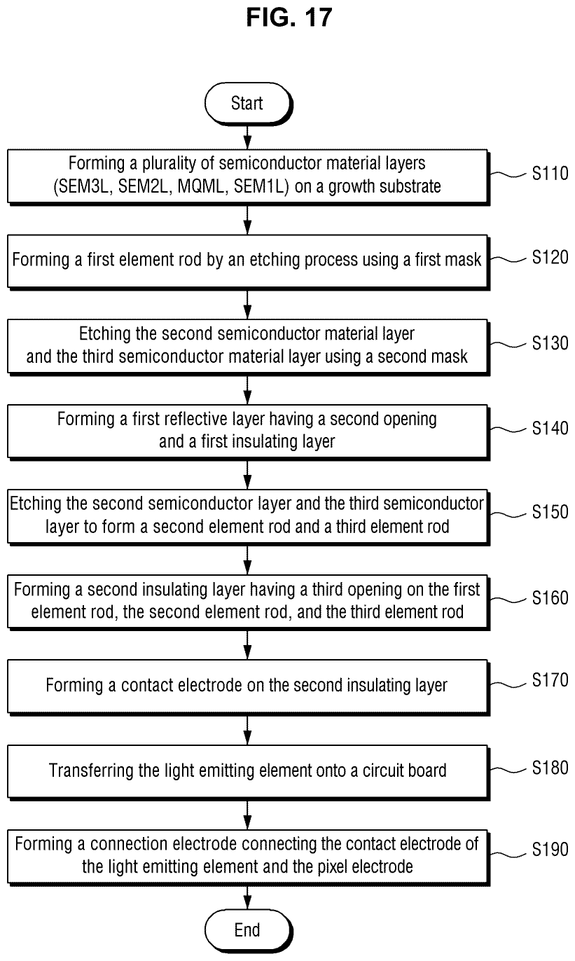

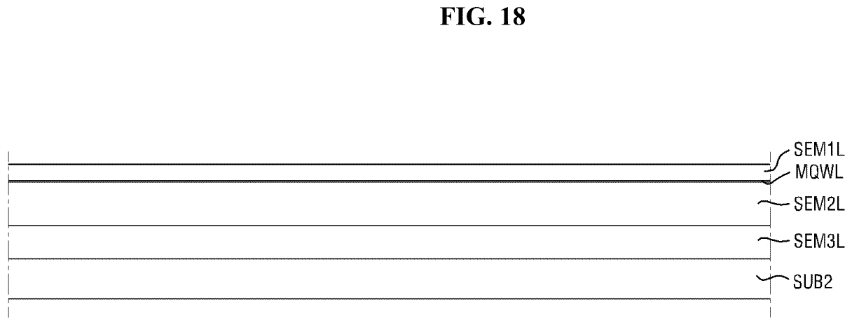

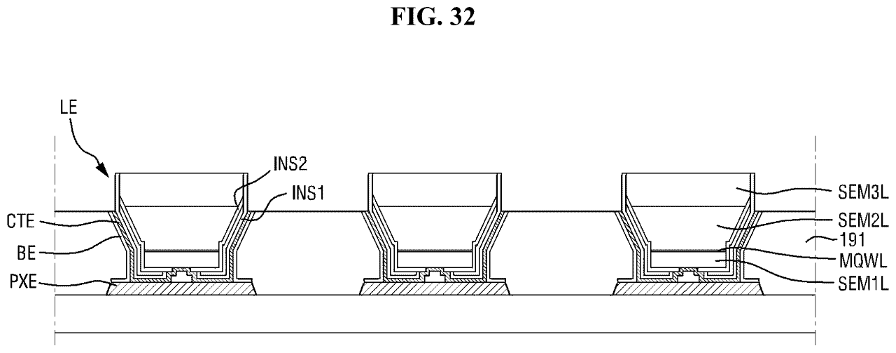

FIG. 17 is a flowchart illustrating a method of manufacturing a display device according to one or more embodiments. FIGS. 18-33 are cross-sectional views to illustrate a method of manufacturing a display device according to one or more embodiments.

FIGS. 18-33 illustrate a structure according to the formation order of the light emitting element (LE of FIGS. 8A-8B) and a structure according to the formation order of each layer of the display panel (100 of FIG. 7) including the light emitting element, respectively, in cross-sectional view. FIGS. 18-33 focus on the formation of the light emitting element and the light emitting element layer (EML of FIG. 7), each of which may correspond roughly to the cross-sectional view of FIG. 7.

A plurality of semiconductor material layers SEM3L, SEM2L, MQWL, and SEM1L are formed on the growth substrate SUB2. A plurality of semiconductor material layers grown by the epitaxial method may be formed by growing a seed crystal. Here, the method of forming the semiconductor material layer may be electron beam deposition, physical vapour deposition (PVD), chemical vapour deposition (CVD), plasma laser deposition (PLD), dual-type thermal evaporation, sputtering, metal organic chemical vapour deposition (MOCVD), and the like, and the semiconductor material layer is preferably formed by metal organic chemical vapour deposition (MOCVD). However, it is not limited thereto.

The precursor material for forming the plurality of semiconductor material layers is not particularly limited within a range that may be conventionally selected to form the target material. In one example, the precursor material may be a metal precursor containing an alkyl group such as a methyl group or an ethyl group. For example, it may be a compound such as trimethyl gallium (Ga(CH₃)₃), trimethyl aluminum (Al(CH₃)₃), and/or triethyl phosphate ((C₂H₅)₃PO₄), but is not limited thereto.

Specifically, the third semiconductor material layer SEM3L is formed on the growth substrate SUB2. The drawings illustrate that the third semiconductor material layer SEM3L is further stacked, but it is not limited thereto, and a plurality of layers may be formed. The third semiconductor material layer SEM3L may be disposed to reduce a lattice constant difference between a second semiconductor material layer SEM2L and the growth substrate SUB2. In one example, the third semiconductor material layer SEM3L may include an undoped semiconductor, which may not be doped with an N-type or P-type dopant. In one or more embodiments, the third semiconductor material layer SEM3L may be undoped InAlGaN, GaN, AlGaN, InGaN, AlN, and/or InN, but is not limited thereto.

The second semiconductor material layer SEM2L, the active material layer MQWL, and the first semiconductor material layer SEM1L are sequentially formed on the third semiconductor material layer SEM3L using the above-described method. In one or more embodiments, a superlattice material layer may be formed between the second semiconductor material layer SEM2L and the active material layer MQWL. Furthermore, an electron blocking material layer may be formed between the active material layer MQWL and the first semiconductor material layer SEM1L. In one or more embodiments, a current spreading layer may be further included on the first semiconductor material layer SEM1L. The current spreading layer may be made of a transparent conductive material (TCO) such as indium tin oxide (ITO) and/or indium zinc oxide (IZO), which may transmit light.

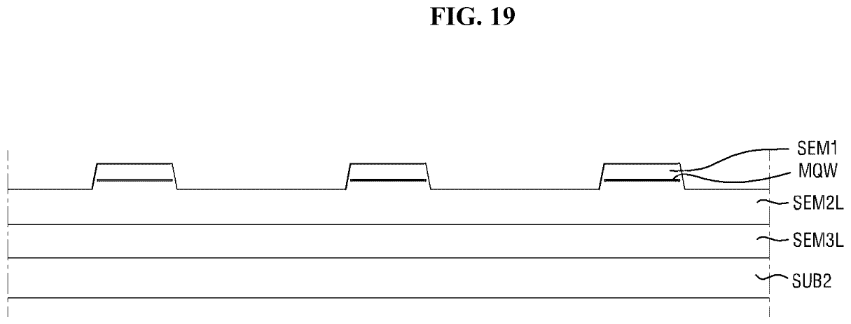

Next, referring to FIG. 19, the first element rod LD1 is formed through an etching process using a first mask. (S120 in FIG. 17)

For example, referring to FIG. 19, at least a first semiconductor material layer SEM1L and an active material layer MQWL of each light emitting element are dry etched using the first mask. At this time, a portion of the second semiconductor layer SEM2 may be further etched.

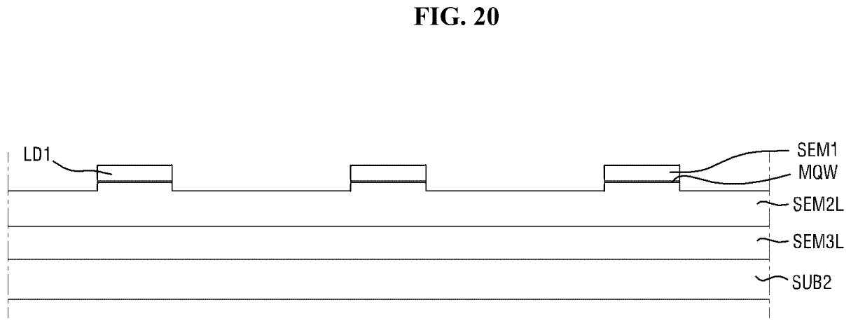

Then, referring to FIG. 20, the first element rod LD1 is wet etched.

During dry etching, as the etching depth increases, the process time increases and the plasma exposure time of the semiconductor material layer increases, which may increase damage to the active layer. Therefore, in one or more embodiments, instead of etching the first semiconductor material layer SEM1L, the active material layer MQWL, the second semiconductor material layer SEM2L, and the third semiconductor material layer SEM3L at once, only the first semiconductor material layer SEM1L, the active material layer MQWL, and a portion of the second semiconductor material layer SEM2L corresponding to about 1/10 of the total semiconductor material layer is etched. Thus, damage to the active layer may be reduced or minimized.

Next, the second semiconductor material layer SEM2L and the third semiconductor material layer SEM3L are etched using a second mask. (S130 in FIG. 17)

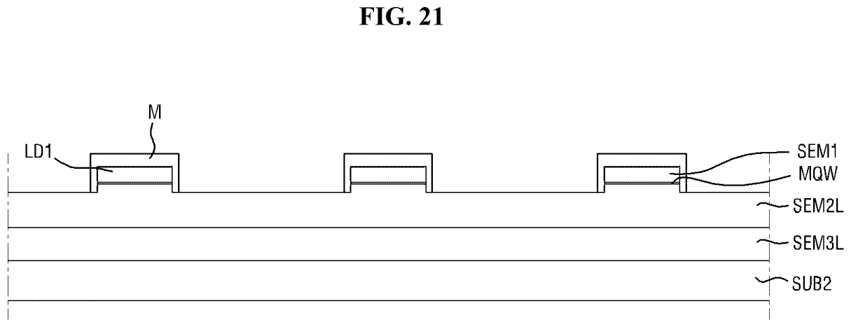

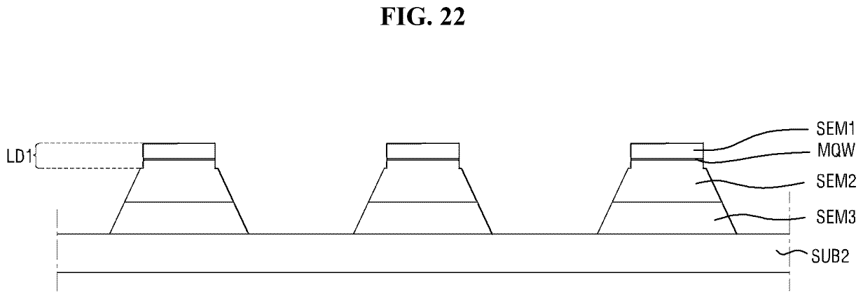

Referring to FIGS. 21 and 22, after forming a hard mask M as a second mask to be around (e.g., to surround or mask) the first element rod LD1, the second semiconductor material layer SEM2L and the third semiconductor material layer SEM3L are patterned using the patterned hard mask M as a mask. For example, the second semiconductor material layer SEM2L and the third semiconductor material layer SEM3L may be etched through a dry etching process. The hard mask may be formed of silicon oxide (SiOₓ).

The slope of the side surfaces of the second semiconductor layer SEM2 and the third semiconductor layer SEM3 may be smaller than that of the first element rod LD1 etched by wet etching. Accordingly, the width may increase from the second semiconductor layer SEM2 to the third semiconductor layer SEM3.

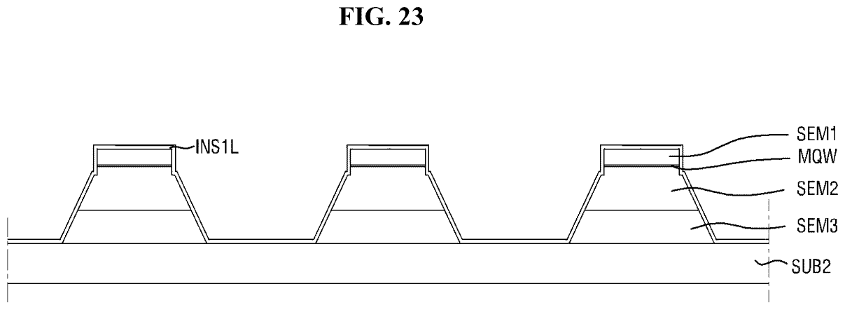

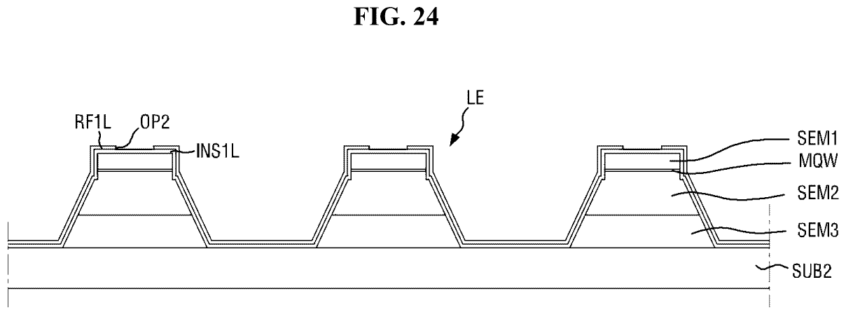

Next, referring to FIGS. 23 and 24, a first reflective layer RF1 having a second opening OP2 and a first insulating layer INS1 are formed. (S140 in FIG. 17)

First, referring to FIG. 23, a first insulating material layer INS1L is formed on the first element rod LD1, the second semiconductor layer SEM2, and the third semiconductor layer SEM3. The first insulating material layer INS1L may be formed of an inorganic film, for example, a silicon nitride film, a silicon oxynitride film, a silicon oxide film, a titanium oxide film, and/or an aluminium oxide film, but is not limited thereto.

Referring to FIG. 24, a first reflective material layer RF1L is deposited to cover the light emitting element LE. Then, a second opening OP2 is formed in the first reflective material layer RF1L on the top surface of the first element rod LD1 of the light emitting element LE using a third mask. The second opening OP2 is formed to expose the first insulating material layer INS1L through the first reflective material layer RF1L on the first element rod LD1.

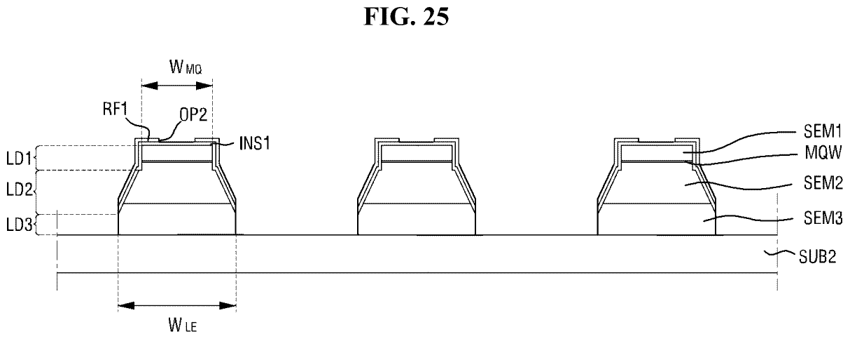

Next, referring to FIG. 25, the second semiconductor layer SEM2 and the third semiconductor layer SEM3 are etched to form the second element rod LD2 and the third element rod LD3. (S150 in FIG. 17). For example, in one or more embodiments, the third element rod LD3 having a third inclination angle θ3 may be formed by etching at least one side surface of the at least one of the first, second, and third semiconductor material layers.

After forming a photoresist covering the area of the light emitting element LE, the photoresist overlapping the opening of the fourth mask is removed to expose the area expect for an area to be the third element rod LD3, and the exposed semiconductor layer is etched to form the second element rod LD2 and the third element rod LD3. The photoresist may be removed by an ashing process.

The portion not etched by the fourth mask becomes the third element rod LD3, and the portion of the second semiconductor layer SEM2 that is not etched by the fourth mask becomes the second element rod LD2. Accordingly, the width of the second element rod LD2 and the third element rod LD3 may be wider than the width of the first element rod LD1. As a result, light emission efficiency may be improved by reducing the width WLE of the light emitting element LE relative to the width WMQ of the active layer MQW. For example, the width WMQ of the active layer MQW relative to the width WLE of the light emitting element LE may be about 0.5 to 0.7, but is not limited thereto, and may be determined by the inclination angle and the length of the second element rod LD2.

In addition, when forming a common electrode CE on the third element rod LD3 formed by the third etching, the disconnection in the common electrode CE at the boundary of the light emitting element may be reduced or minimized compared to when forming a common electrode on the element rod formed by second etching.

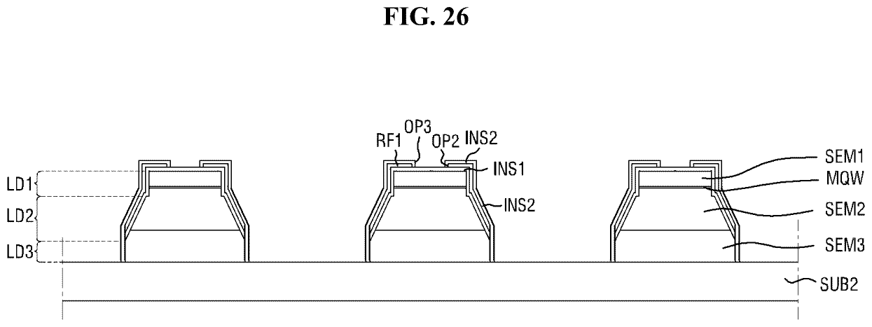

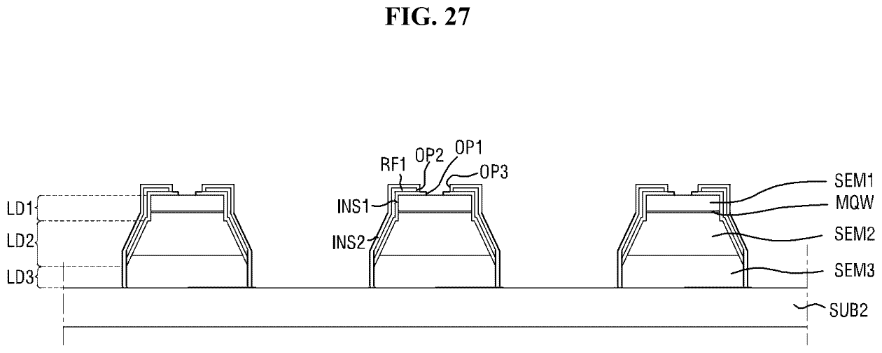

Next, referring to FIGS. 26 and 27, a second insulating layer INS2 having a third opening OP3 on the first element rod LD1, the second element rod LD2, and the third element rod LD3. (S160 in FIG. 17)

A second insulating material layer is formed on the first element rod LD1, the second semiconductor layer SEM2, and the third semiconductor layer SEM3. Then, a third opening OP3 overlapping the second opening OP2 is formed in the second insulating material layer on the first element rod LD1.

Next, a first opening OP1 overlapping the second opening OP2 and the third opening OP3 is formed in the first insulating layer INS1 on the first element rod LD1 using a fifth mask. Accordingly, on the first element LD1, the first semiconductor layer SEM1 may be exposed by the openings OP1, OP2, and OP3 penetrating the first insulating layer INS1, the first reflective layer RF1, and the second insulating layer INS2.

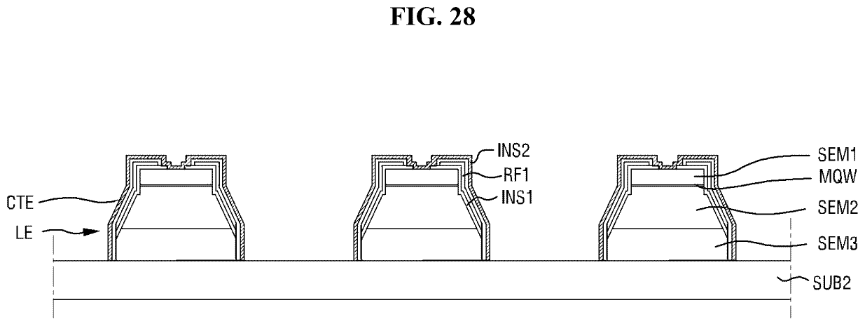

Next, referring to FIG. 28, a contact electrode CTE electrically connected to the first semiconductor layer SEM1 is formed on the second insulating layer INS2 (S170 in FIG. 17).

A contact electrode CTE is formed to cover the light emitting element LE. The contact electrode CTE may be electrically connected to the first semiconductor layer SEM1 by the openings OP1, OP2, and OP3. The contact electrode CTE may be in direct contact with the first semiconductor layer SEM1 by the openings OP1, OP2, and OP3. The contact electrode CTE may include gold (Au), copper (Cu), tin (Sn), silver (Ag), aluminium (Al), and/or titanium (Ti). In another variant, when the first semiconductor layer SEM1 has a current spreading layer, etc., the contact electrode CTE may be in direct contact with the current spreading layer and may be electrically connected to the first semiconductor layer SEM1.

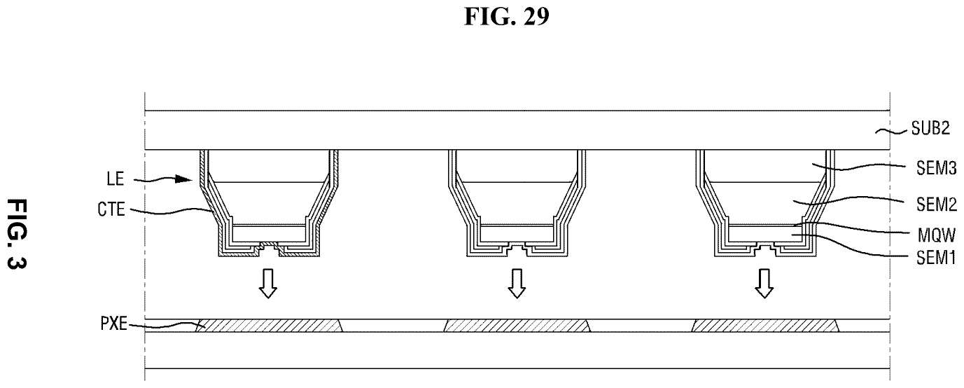

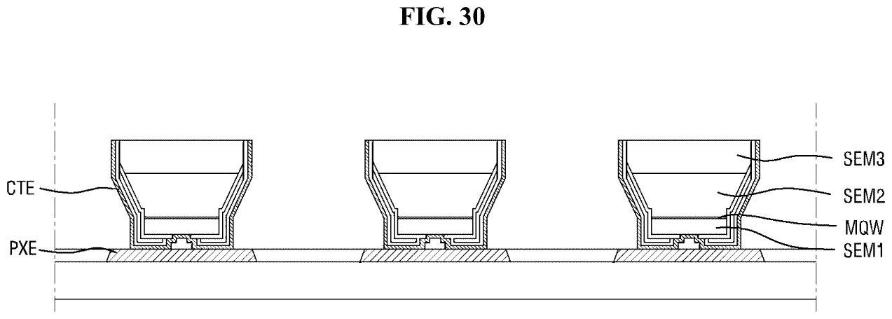

Then, referring to FIGS. 29 and 30, the light emitting element LE is transferred onto a circuit board (S180 in FIG. 17).

For convenience of explanation, it is illustrated that the light emitting elements LE on the growth substrate SUB2 are transferred onto the circuit board, but the light emitting elements LE on the growth substrate SUB2 may be transferred to a relay substrate or the like multiple times and then transferred to the circuit board. Alternatively, it may be transferred onto the circuit board using a stamp or the like.

The first element rod LD1 of the light emitting elements LE is aligned to be positioned on the pixel electrode PXE. Then, the growth substrate SUB2 is separated from the light emitting elements LE and removed. For example, the plurality of light emitting elements LE may be separated from the growth substrate SUB2 using a laser lift process.

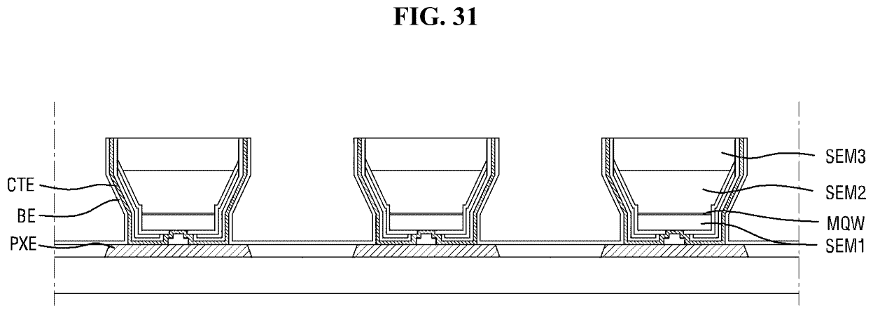

Thereafter, referring to FIG. 31, a connection electrode BE is formed to connect the contact electrode CTE of the light emitting element LE and the pixel electrode PXE (S190 in FIG. 17).

For this purpose, a connection electrode layer covering each pixel electrode PXE and a plurality of light emitting elements LE is first formed. After forming a photoresist that covers the entire connection electrode layer, the photoresist overlapping the opening of the mask is removed to expose the connection electrode layer between each pixel electrode, and then the exposed connection electrode layer is etched to form the connection electrode BE. The photoresist may be removed by an ashing process. The connection electrode BE may serve as a bonding metal for bonding the pixel electrodes PXE and the light emitting elements LE.

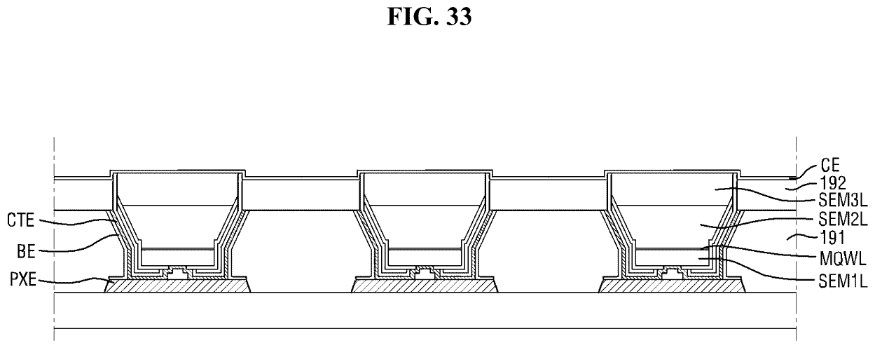

Referring to FIG. 33, a fourth organic film 192 is formed on the third organic film 191, and then a common electrode CE is formed on the fourth organic film 192 and the light emitting elements LE.

Referring to FIG. 33, a common electrode CE is formed on the third organic film 191 and the light emitting elements LE.

Then, the light blocking layer BM, the first and second light conversion layers QDL1 and QDL2, the light transmission layer TPL, and the color filters CF1, CF2, and CF3 are formed.

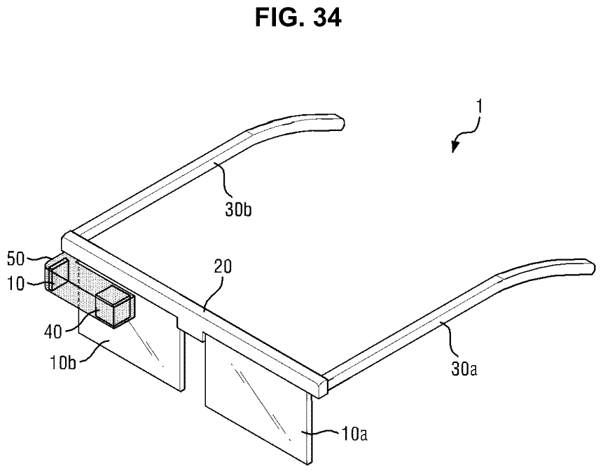

FIG. 34 is an example diagram illustrating a virtual reality device including a display device according to one or more embodiments. FIG. 34 illustrates a virtual reality device 1 in which the display device 10 according to one or more embodiments is used.

Referring to FIG. 34, the virtual reality device 1 according to one or more embodiments may be a device in a form of glasses. The virtual reality device 1 according to one or more embodiments may include a display device 10, a left-eye lens 10a, a right-eye lens 10b, a support frame 20, left and right legs 30a and 30b, a reflective member 40, and a display device housing 50.

FIG. 34 illustrates the virtual reality device 1 including the two legs 30a and 30b. However, the present disclosure is not limited thereto. The virtual reality device 1 according to one or more embodiments may be used in a head-mounted display including a head-mounted band that may be mounted on a head instead of the legs 30a and 30b. For example, the virtual reality device 1 according to one or more embodiments may not be limited to the example shown in FIG. 34, and may be applied in various forms and in various electronic devices.

The display device housing 50 may receive the display device 10 and the reflective member 40. An image displayed on the display device 10 may be reflected from the reflective member 40 and provided to a user's right eye through the right-eye lens 10b. Thus, the user may view a virtual reality image displayed on the display device 10 via the right eye.

FIG. 34 illustrates that the display device housing 50 is disposed at a right end of the support frame 20. However, the present disclosure is not limited thereto. For example, the display device housing 50 may be disposed at a left end of the support frame 20. In this case, the image displayed on the display device 10 may be reflected from the reflective member 40 and provided to the user's left eye via the left-eye lens 10a. Thus, the user may view the virtual reality image displayed on the display device 10 via the left eye. As another example, the display device housing 50 may be disposed at each of the left end and the right end of the support frame 20. In this case, the user may view the virtual reality image displayed on the display device 10 via both the left eye and the right eye.

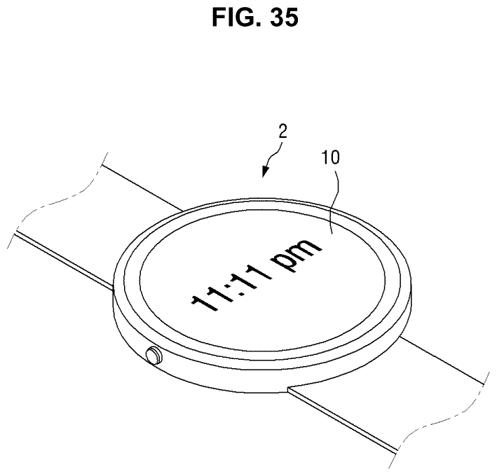

FIG. 35 is an example diagram illustrating a smart device including a display device according to one or more embodiments.

Referring to FIG. 35, a display device 10 according to one or more embodiments may be applied to a smart watch 2 as one of smart devices.

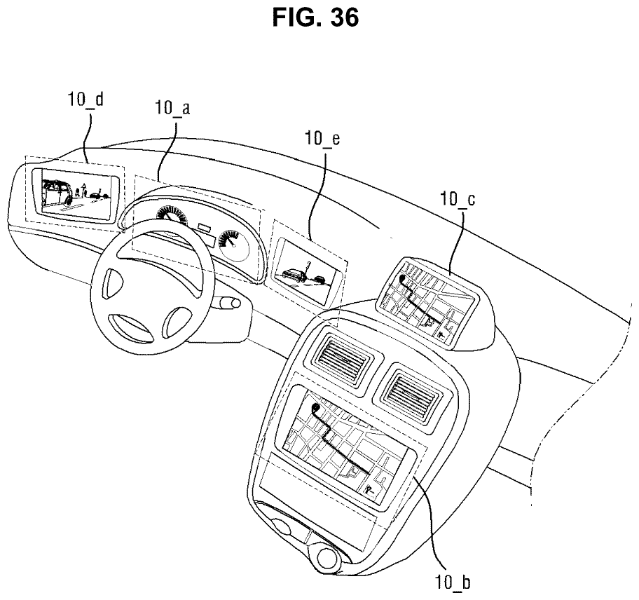

FIG. 36 is an example diagram illustrating a vehicle including a display device according to one or more embodiments. FIG. 36 illustrates a vehicle in which display devices according to one or more embodiments are used.

Referring to FIG. 36, the display devices 10_a, 10_b, and 10_c according to one or more embodiments may be applied to the dashboard of the vehicle, applied to the center fascia of the vehicle, or applied to a Center Information Display (CID) disposed on the dashboard of the vehicle. Further, each of the display devices 10_d and 10_e according to one or more embodiments may be applied to each room mirror display that replaces each of side-view mirrors of the vehicle.

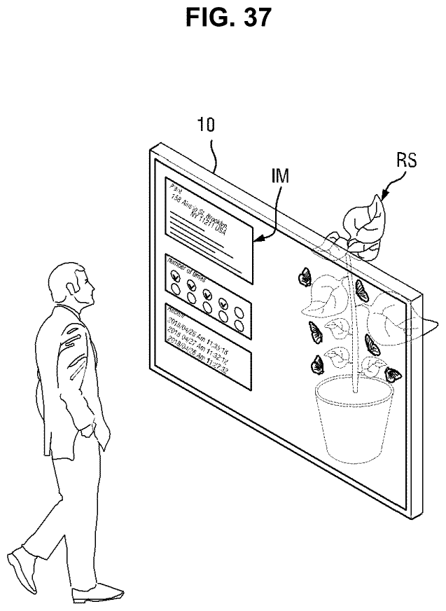

FIG. 37 is an example diagram illustrating a transparent display device including a display device according to one or more embodiments.

Referring to FIG. 37, a display device according to one or more embodiments may be applied to a transparent display device. The transparent display device may transmit light therethrough while displaying an image IM thereon. Therefore, a user located in front of the transparent display device may not only view the image IM displayed on the display device 10, but also view an object RS or a background located in rear of the transparent display device. In case that the display device 10 is applied to the transparent display device, the substrate SUB of the display device 10 shown in FIG. 7 may include a light transmitting portion that may transmit light therethrough or may be made of a material that may transmit light therethrough.

In concluding the detailed description, those skilled in the art will appreciate that many variations and modifications can be made to the embodiments without substantially departing from the principles and scope of the present disclosure. Therefore, the embodiments of the present disclosure are used in a generic and descriptive sense only and not for purposes of limitation.

What is claimed is:

1. A light emitting element comprising:
a first element rod comprising a first semiconductor layer and an active layer and having a first inclination angle on a side surface;
a second element rod on the first element rod and having a second inclination angle on a side surface;
a third element rod on the second element rod and having a third inclination angle on a side surface, the second inclination angle being smaller than the first inclination angle and the third inclination angle;
a protective layer around one surface and an side of the first element rod, a side of the second element rod, and a side of the third element rod; and
a contact electrode around the protective layer and electrically connected to the first semiconductor layer.

2. The light emitting element of claim 1, wherein the second inclination angle is in a range from 60 degrees to 80 degrees.

3. The light emitting element of claim 1, wherein the protective layer comprises:
a first insulating layer around the one surface and the side of the first element rod, and the side of the second element rod;
a reflective layer around the one surface and the side of the first element rod and the side of the second element rod on the first insulating layer; and
a second insulating layer around the surface side and the side of the first element rod, the side of the second element rod, and the side of the third element rod on the reflective layer.

4. The light emitting element of claim 3, wherein the first insulating layer and the reflective layer are not on the side of the third element rod.

5. The light emitting element of claim 1, wherein the second element rod is wider toward the third element rod, and a width of the third element rod is greater than a width of the first element rod.

6. The light emitting element of claim 4, wherein the contact electrode extends from the one surface of the first element rod and is on at least a portion of the side of the first element rod, the side of the second element rod, and the side of the third element rod.

7. A light emitting element comprising:
an element rod comprising a first semiconductor layer, an active layer, a second semiconductor layer, and a third semiconductor layer stacked in order, and divided into a first element rod, a second element rod, and a third element rod according to an inclination angle, the first element rod comprising the first semiconductor layer and an active layer, the inclination angle comprising a first inclination angle, a second inclination angle, and a third inclination angle, the second inclination angle of the second element rod being smaller than the first inclination angle of the first element rod and the third inclination angle of the third element rod;
a protective layer around one surface and a side of the first element rod, a side of the second element rod, and a side of the third element rod; and
a first contact electrode and a second contact electrode spaced from each other on the one surface of the first element rod, the first contact electrode electrically connected with the first semiconductor layer, the second contact electrode being electrically connected with the second semiconductor layer.

8. The light emitting element of claim 7, wherein the protective layer comprises:
a first insulating layer around the one surface and the side of the first element rod and the side of the second element rod;
a reflective layer around the one surface and the side of the first element rod and the side of the second element rod on the first insulating layer; and
a second insulating layer around the one surface and the side of the first element rod, the side of the second element rod, and the side of the third element rod on the reflective layer.

9. The light emitting element of claim 7, wherein the first contact electrode and the second contact electrode are disposed on at least a portion of a side surface of the element rod on the protective layer.

10. A display device comprising:
a substrate;
a pixel electrode on the substrate;
a light emitting element on the pixel electrode and comprising a contact electrode on one surface;
a connection electrode connecting the contact electrode and the pixel electrode; and
a common electrode on the light emitting element, the light emitting element further comprising:
a first element rod comprising a first semiconductor layer and an active layer and having a first inclination angle on a side surface;
a second element rod on the first element rod and having a second inclination angle on a side surface;
a third element rod on the second element rod and having a third inclination angle on a side surface; and
a protective layer around one surface and a side of the first element rod, a side of the second element rod, and a side of the third element rod,
the contact electrode being around at least a portion of a side of the protective layer, and the second inclination angle being smaller than the first inclination angle and the third inclination angle.

11. The display device of claim 10, wherein the second inclination angle is in a range from 60 degrees to 80 degrees.

12. The display device of claim 10, wherein the protective layer comprises:
a first insulating layer around the one surface and the side of the first element rod and the side of the second element rod;
a reflective layer around the one surface and the side of the first element rod and the side of the second element rod on the first insulating layer; and
a second insulating layer around the one surface and the side of the first element rod, the side of the second element rod, and the side of the third element rod on the reflective layer.

13. The display device of claim 12, wherein the first insulating layer and the reflective layer are not on the side of the third element rod.

14. The display device of claim 13, wherein the contact electrode extends from the one surface of the first element rod and is on at least a portion of the side of the first element rod, the side of the second element rod, and the side of the third element rod.

15. The display device of claim 10, further comprising:
an organic pattern layer between the light emitting element and the pixel electrode,
wherein the connection electrode is on a portion of a side surface of the organic pattern layer and a side surface of the contact electrode on the pixel electrode.

16. A display device comprising:
a substrate;
a pixel electrode and a common electrode on the substrate and spaced from each other;
a light emitting element on the pixel electrode and the common electrode and comprising a first contact electrode and a second contact electrode on one surface;
a first connection electrode connected to the pixel electrode and the first contact electrode; and
a second connection electrode connected to the common electrode and the second contact electrode,
the light emitting element comprising
an element rod comprising a first semiconductor layer, an active layer, a second semiconductor layer, and a third semiconductor layer stacked in order, and divided into a first element rod, a second element rod, and a third element rod according to an inclination angle, the inclination angle comprising a first inclination angle, a second inclination angle, and a third inclination angle, the second inclination angle of the second element rod being smaller than the first inclination angle of the first element rod and the third inclination angle of the third element rod; and
a protective layer around a one surface and a side of the first element rod, a side of the second element rod, and a side of the third element rod, and
the first contact electrode and the second contact electrode being spaced from each other on the one surface of the first element rod and on at least a portion of a side surface of the element rod on the protective layer.

17. The display device of claim 16, wherein the protective layer comprises:
a first insulating layer around the one surface and the side of the first element rod and the side of the second element rod;
a reflective layer around the one surface and the side of the first element rod and the side of the second element rod on the first insulating layer; and
a second insulating layer around the one surface and the side of the first element rod, the side of the second element rod, and the side of the third element rod on the reflective layer.

18. The display device of claim 16, further comprising:
an organic pattern layer between the pixel electrode and the common electrode,
wherein the light emitting element is on the organic pattern layer,
wherein the first connection electrode is on a portion of a side surface of the organic pattern layer and a side surface of the first contact electrode, and
wherein the second connection electrode is on another part of the side surface of the organic pattern layer and a side surface of the second contact electrode.

19. A method of manufacturing light emitting element comprising:
forming a third semiconductor material layer, a second semiconductor material layer, an active material layer, and a first semiconductor material layer on a growth substrate;
forming a first element rod having a first inclination angle by etching the active material layer and the first semiconductor material layer using a first mask;
masking the first element rod using a second mask and etching the second semiconductor material layer and the third semiconductor material layer;
forming a first insulating layer and a first reflective layer covering the third semiconductor material layer, the second semiconductor material layer, the active material layer, and the first semiconductor material layer;
forming a second element rod having a second inclination angle and a third element rod having a third inclination angle by etching at least one side surface of at least one of the first, second, and third semiconductor material layers, the first insulating layer, and the first reflective layer using a third mask;
forming a second insulating layer covering the third semiconductor material layer, the second semiconductor material layer, the active material layer, and the first semiconductor material layer; and
forming a contact electrode on the second insulating layer.

20. A method of manufacturing display device comprising:
forming a third semiconductor material layer, a second semiconductor material layer, an active material layer, and a first semiconductor material layer on a growth substrate;
forming a first element rod having a first inclination angle by etching the active material layer and the first semiconductor material layer using a first mask;
masking the first element rod using a second mask and then etching the second semiconductor material layer and the third semiconductor material layer;
forming a first insulating layer and a first reflective layer covering the third semiconductor material layer, the second semiconductor material layer, the active material layer, and the first semiconductor material layer;
forming a second element rod having a second inclination angle and a third element rod having a third inclination angle by etching at least one side surface of at least one of the first, second, and third semiconductor material layers, the first insulating layer, and the first reflective layer using a third mask;
forming a second insulating layer covering the third semiconductor material layer, the second semiconductor material layer, the active material layer, and the first semiconductor material layer;
forming a light emitting element by forming a contact electrode on the second insulating layer;
transferring the light emitting element to a circuit board having a pixel electrode; and
forming a connection electrode connecting the contact electrode and the pixel electrode.
